(19) United States
(12) Patent Application Publication
(10) Pub. No.: US 2022/0344455 A1
(43) Pub. Date: Oct. 27, 2022

(54) SEMICONDUCTOR DEVICE

(71) Applicant: FUJI ELECTRIC CO., LTD., Kawasaki-shi (JP)

(72) Inventors: Yasuyuki HOSHI, Matsumoto-city (JP); Tomohiro MORIYA, Matsumoto-city (JP)

(73) Assignee: FUJI ELECTRIC CO., LTD., Kawasaki-shi (JP)

(21) Appl. No.: 17/682,687

(22) Filed: Feb. 28, 2022

(30) Foreign Application Priority Data
Apr. 23, 2021 (JP) 2021-072957

(51) Int. Cl. H01L 29/06; H01L 29/78; H01L 29/16

(52) U.S. Cl. CPC H01L 29/0619; H01L 29/7811; H01L 29/1608

(57) ABSTRACT

A FLR structure is provided in an edge termination region as a voltage withstanding structure. The FLR structure is configured by multiple FLRs that concentrically surround a periphery of an active region. An impurity concentration of the FLRs is less than 1×10¹⁸/cm³ or preferably, may be in a range of 3×10¹⁷/cm³ to 9×10¹⁷/cm³. A thickness of each of the FLRs is in a range of 0.7 μm to 1.1 μm. A first interval between an innermost FLR and an outer peripheral pt-type region is at most about 1.2 μm.

### CROSS REFERENCE TO RELATED APPLICATIONS

This application is based upon and claims the benefit of priority of the prior Japanese Patent Application No. 2021-072957, filed on Apr. 23, 2021, the entire contents of which are incorporated herein by reference.

### BACKGROUND OF THE INVENTION

### 1. Field of the Invention

Embodiments of the invention relate to a semiconductor device.

### 2. Description of the Related Art

Among power semiconductor devices that control high voltage and/or large current, there are several types such as bipolar transistors, insulated gate bipolar transistors (IGBTs), and metal oxide semiconductor field effect transistors (MOSFETs) that have insulated gates (MOS gates) having a 3-layer structure including a metal, an oxide film, and a semiconductor; these devices are selectively used according to an intended purpose.

For example, bipolar transistors and IGBTs have high current density compared to MOSFETs and can be adapted for large current but cannot be switched at high speeds. In particular, the limit of switching frequency is about several kHz for bipolar transistors and about several tens of kHz for IGBTs. On the other hand, MOSFETs have low current density compared to bipolar transistors and IGBTs and are difficult to adapt for large current but can be switched at high speeds up to about several MHz.

Further, a MOSFET, unlike an IGBT, has a built-in parasitic diode (body diode) formed by pn junctions between an n⁻-type drift region and p-type base regions in a semiconductor substrate (semiconductor chip). The MOSFET may use the parasitic diode built in the semiconductor substrate to function as a freewheeling diode for protecting the MOSEFT. Therefore, the MOSFET is also attracting attention economically as additional connection of an external freewheel diode is unnecessary.

While silicon (Si) is used as material for fabricating power semiconductor devices, there is a strong demand in the market for large-current, high-speed power semiconductor devices and thus, IGBTs and power MOSFETs have been intensively developed and improved, and the performance of power devices has substantially reached the theoretical limit determined by the material. Therefore, in terms of power semiconductor devices, semiconductor materials to replace silicon have been investigated and silicon carbide (SiC) has been focused on as a semiconductor material enabling fabrication (manufacture) of a next-generation power semiconductor device having low ON voltage, high-speed characteristics, and high-temperature characteristics.

SiC is a very stable material chemically, has a wide bandgap of 3 eV, and can be used very stably as a semiconductor material even at high temperatures. Further, SiC has a critical electric field strength that is at least ten times that of silicon and therefore, is expected to be a semiconductor material capable of sufficiently reducing ON resistance. Such characteristics of silicon carbide are also applicable to other semiconductors having a band gap wider than a band gap of silicon (hereinafter, wide band gap semiconductors).

Further, in a high-voltage semiconductor device, high voltage is applied to not only an active region in which a device element structure is formed, but also to an edge termination region that surrounds a periphery of the active region, and electric field concentrates in the edge termination region. Breakdown voltage of the semiconductor device is determined by an impurity concentration, thickness, and electric field strength of the semiconductor (drift region); destruction resistance is determined by these characteristics unique to the semiconductor and is constant in the active region and the edge termination region. Therefore, when electric field concentrates in the edge termination region and an electrical load exceeding the destruction resistance is applied to the edge termination region, destruction may occur in the edge termination region.

In this regard, a structure that enhances the overall breakdown voltage of a semiconductor device is commonly known in which a voltage withstanding structure such as a junction termination extension (JTE) structure, a field limiting ring (FLR) structure, etc. is disposed in the edge termination region, thereby mitigating or dispersing the electric field of the edge termination region, whereby the breakdown voltage of the edge termination region is enhanced. Further, a structure is commonly known in which a metal electrode with a floating potential is in contact with a FLR and provided in the edge termination region as a field plate (FP) and charge generated in the edge termination region is discharged, whereby reliability of the semiconductor device is enhanced.

A structure of a conventional silicon carbide semiconductor device is described. FIG. 18 is a cross-sectional view depicting the structure of the conventional silicon carbide semiconductor device. In FIG. 18, FLRs 221, 222 are indicated by different hatching. A conventional semiconductor device 230 depicted in FIG. 18 is a vertical MOSFET that has a trench gate structure and includes an active region 201 through which a main current flows and an edge termination region 202 surrounding a periphery of the active region 201, on a semiconductor substrate 210 containing silicon carbide. In the semiconductor substrate 210, epitaxial layers 272, 273 constituting an n⁻-type drift region 232 and a p-type base region 234, respectively, are sequentially formed by epitaxial growth on an n⁺-type starting substrate 271 containing silicon carbide.

A portion of the p-type epitaxial layer 273 in the edge termination region 202 is removed by etching and at a front surface of the semiconductor substrate 210, a drop 253 is formed in the edge termination region 202. With the drop 253 as a boundary, the front surface of the semiconductor substrate 210 is recessed toward a drain electrode 252 at a second surface portion 210b that is closer to a chip outer side (chip end (end of the semiconductor substrate 210) side) than is a first surface portion 210a that is closer to a chip inner side (chip center (center of the semiconductor substrate 210) side). Due to the drop 253, the p-type epitaxial layer 273 is left in a mesa shape at the front surface of the semiconductor substrate 210 (main surface having the p-type epitaxial layer 273) in a chip center portion.

The first and the second surface portions 210a, 210b of the front surface of the semiconductor substrate 210 are formed by the p-type epitaxial layer 273 and the n⁻-type the epitaxial layer 272, respectively. In the first surface portion 210a of the front surface of the semiconductor substrate 210 MOS gates of the trench gate structure are provided in the active region 201. In the edge termination region 202, in surface regions at the second surface portion 210b of the front surface of the semiconductor substrate 210, a spatially modulated FLR structure 220 is configured by multiple p⁻-type regions (FLRs) 221 and multiple p⁻⁻-type regions (FLRs) 222 selectively provided in the n⁻-type the epitaxial layer 272.

The spatially modulated FLR structure 220 is a voltage withstanding structure having a p-type impurity concentration per unit area that decreases stepwise in a direction toward the chip end. In particular, the FLRs 221 are disposed separately from one another concentrically surrounding a periphery of the active region 201. The closer a FLR 221 of the FLRs 221 is disposed to the chip end, the narrower is a width (width in direction of the normal) of said FLR 221 and the narrower is an interval between said FLR 221 and another FLR 221 that is adjacent thereto of the FLRs 221 and closer to the chip center than is said FLR 221. Of the FLRs 222, a FLR 222 closest to the chip center surrounds peripheries of all the FLRs 221 and is disposed between all the FLRs 221 adjacent to one another. Of the FLRs 221, a FLR 221 closest to the chip center and of the FLRs 222, the FLR 222 closest to the chip center are electrically connected to the p-type base region 234 (234a).

The FLRs 222 are disposed separately from one another and concentrically surround a periphery of the active region 201. The closer a FLR 222 of the FLRs 222 is to the chip end, the narrower is a width (width in the direction of the normal) thereof and the narrower is an interval between said FLR 222 and another FLR adjacent 222 that is thereto of the FLRs 222 and closer to the chip center than is said FLR. The FLRs 222 excluding the FLR 222 closest to the chip center are disposed closer to the chip end than are the FLRs 221. The n⁻-type drift region 232 surrounds the peripheries of all the FLRs 221 and is disposed between all the FLRs 221 adjacent to one another. Optimized conditions for the widths and arrangement of the FLRs 221 and the FLRs 222 have been disclosed (for example, refer to Japanese Patent No. 6323570 and Japanese Patent No. 6610786).

Reference numeral 203 is an intermediate region between the active region 201 and the edge termination region 202. Reference character 210c is a third surface portion (mesa edge of the drop) connecting the first surface portion 210a of the front surface of the semiconductor substrate 210 and the second surface portion 210b. Reference characters 231, 233, 235, 236, 238, 239, 240, 240a, 241, 281, 282, and 283 are an n⁺-type drain region, n-type current spreading regions, n⁺-type source regions, p⁺⁺-type contact regions, gate insulating films, gate electrodes, an interlayer insulating film, contact holes, a metal silicide film, a field oxide film, a gate polysilicon wiring layer, and a gate metal wiring layer, respectively.

Reference numerals 241, 242, 243, 244, and 245 are metal films configuring a barrier metal 246. Reference numerals 248 and 249 are a plating film and a terminal pin configuring a wiring structure on a source pad 247. Reference numeral 250 and 251 are protective films (passivation films). Reference numerals 261 and 262 are p⁺-type regions for mitigating electric field near bottoms of trenches 237. Reference characters 262a, 234a, and 236a are portions of the p⁺-type region 262, the p-type base region 234, and the p⁺⁺-type contact region 236 extending from the active region 201 into the intermediate region 203. Reference numeral 223 is an n⁺-type channel stopper region.

Another structure of a conventional silicon carbide semiconductor device is described. FIG. 19 is a cross-sectional view depicting another structure of a conventional silicon carbide semiconductor device. A conventional semiconductor device 260 depicted in FIG. 19 differs from the conventional semiconductor device 230 depicted in FIG. 18 in that the voltage withstanding structure in the edge termination region 202 is an ordinary FLR structure 290 instead of the spatially modulated FLR structure 220. In the conventional semiconductor device 260 depicted in FIG. 19 as well, similarly to the conventional semiconductor device 230 depicted in FIG. 18, the second surface portion 210b of the front surface of the semiconductor substrate 210 is covered by an insulating layer such as the field oxide film 281 and the interlayer insulating film 240 without a field plating being disposed.

The ordinary FLR structure 290 is configured by multiple (herein, 18) p⁻-type regions (FLRs (hatched portions)) 291 having a floating potential and selectively provided in the n⁻-type the epitaxial layer 272, in surface regions thereof at the second surface portion 210b of the front surface of the semiconductor substrate 210. Of the pt-type regions 262, one (hereinafter, outer peripheral pt-type region) 262a extends from the active region 201 into the intermediate region 203 and of the FLRs 291, a FLR 291 closest to the chip center is disposed apart from the outer peripheral pt-type region 262a by a predetermined width (first interval) w211 and is closer to the chip end than is the outer peripheral pt-type region 262a. The FLRs 291 are disposed apart from one another and concentrically surround the active region 201 via the intermediate region 203.

All the FLRs 291 have a substantially rectangular shape of a same configuration in a cross-sectional view thereof with substantially a same width w210, substantially a same thickness t201, and substantially a same impurity concentration. The impurity concentration of the FLRs 291 is lower than an impurity concentration of the outer peripheral pt-type region 262a and, for example, is at least about 5×10¹⁸/cm³ in an instance of a breakdown voltage of at least about 1200V. The FLRs 291 are disposed at a substantially equal interval w212. Substantially the same (substantially equal) width, thickness, interval, and impurity concentration means the same width, the same thickness, the same interval, and the same impurity concentration within a range including allowable error due to process variation.

All the FLRs 291 terminate at positions shallower from the front surface of the semiconductor substrate 210 than does the outer peripheral pt-type region 262a. The thickness t201 of the FLRs 291 is, for example, about 0.4 μm to 0.5 μm from the second surface portion 210b of the front surface of the semiconductor substrate 210. To obtain the same breakdown voltage by the ordinary FLR structure 290 as the breakdown voltage obtained by the spatially modulated FLR structure 220, a length (length from the intermediate region 203 to the chip end) w202 of the edge termination region 202 has to be about two times a length w201 of the edge termination region 202 in an instance in which the voltage withstanding structure is the spatially modulated FLR structure 220 (refer to FIG. 18) and, for example, is about 300 μm.

Various types of JTE structures and ordinary FLR structures have been disclosed (for example, refer to Japanese Laid-Open Patent Publication No. 2006-165225, Japanese Laid-Open Patent Publication No. 2018-022851, Japanese Laid-Open Patent Publication No. 2018-082056, Japanese Laid-Open Patent Publication No. 2010-050147, Japanese Laid-Open Patent Publication No. 2016-225455, Japanese Laid-Open Patent Publication No. 2019-054087, and Japanese Patent No. 5011612). In Japanese Laid-Open Patent Publication No. 2006-165225, positioning and impurity concentration ranges in an instance in which a JTE structure is configured by two p-type regions are disclosed. In Japanese Laid-Open Patent Publication No. 2018-022851, p⁻-type regions configuring a JTE structure are disposed at deep positions apart from the front surface of the semiconductor substrate, whereby electric field applied to end corner portions of p-type base regions is mitigated and the breakdown voltage is enhanced. In Japanese Laid-Open Patent Publication No. 2018-082056, a thickness of a p-type silicon carbide layer extended into the edge termination region from the active region decreases stepwise, whereby a JTE structure is formed in which an effective impurity concentration decreases with increasing proximity to the chip end.

Japanese Laid-Open Patent Publication No. 2010-050147 discloses an ordinary FLR structure having a field plate. In Japanese Laid-Open Patent Publication No. 2010-050147, field plates that are provided, respectively, via an interlayer insulating film, on FLRs configuring an ordinary FLR structure are extended from positions on the FLRs to positions on portions (n⁻-type drift region) between FLRs that are adjacent to one another. A thickness of a portion of the interlayer insulating film covering the FLRs is less than a thickness of a portion covering the n⁻-type drift region between the FLRs that are adjacent to one another, whereby effects of electrostatic capacity of the interlayer insulating film are suppressed and reliability is enhanced without optimization of the structure of the field plate.

In Japanese Laid-Open Patent Publication No. 2016-225455, Japanese Laid-Open Patent Publication No. 2019-054087, and Japanese Patent No. 5011612, an ordinary FLR structure having field plates is disclosed. Japanese Laid-Open Patent Publication No. 2016-225455 and Japanese Laid-Open Patent Publication No. 2019-054087 disclose that FLRs (pt-type regions) and pt-type regions for mitigating electric field near trench bottoms are formed concurrently. Further, in Japanese Laid-Open Patent Publication No. 2019-054087, FLRs (p⁻-type regions) are disposed at deep positions apart from the front surface of the semiconductor substrate, and pn junctions between the FLRs and an n⁻-type drift region are apart from the front surface of the semiconductor substrate, whereby increases in electric field strength at an uppermost surface of an interlayer insulating film on the front surface of the semiconductor substrate is suppressed and occurrence of creepage destruction of the interlayer insulating film is suppressed.

In Japanese Patent No. 5011612, an interval between a p-type well region of an active region and a FLR that is closest to the chip center of the FLRs and an interval between an adjacent two of the FLRs are adjusted with respect to a depletion layer that spreads in a direction from the active region to the chip end and p-type regions adjacent to these are disposed sufficiently close to each other, whereby electric field strength that increases by shape effects due to a curvature of a p-type spreading region constituted by the p-type well region and/or the FLRs is suppressed. Japanese Patent No. 5011612 discloses that the interval between the p-type well region of the active region and the FLR that is closest to the chip center is assumed to be in a range of 0 μm to 1 μm, and an interval between an adjacent two of the FLRs increases by an increment of 0.5 μm the closer the adjacent two of the FLRs are disposed to the chip end.

### SUMMARY OF THE INVENTION

According to an embodiment of the invention, a semiconductor device having an active region through which a main current flows and a termination region surrounding a periphery of the active region, the semiconductor device includes a semiconductor substrate containing a semiconductor having a band gap wider than a band gap of silicon, the semiconductor substrate having a first main surface and a second main surface opposite to each other; a first semiconductor region of a first conductivity type, provided in the semiconductor substrate; a second semiconductor region of a second conductivity type, provided in the active region, between the first main surface of the semiconductor substrate and the first semiconductor region; a device element structure formed in the active region, and including a pn junction between the second semiconductor region and the first semiconductor region; a first electrode electrically connected to the second semiconductor region; a second electrode provided on the second main surface of the semiconductor substrate; and a plurality of second-conductivity-type voltage withstanding regions selectively provided apart from one another in the first semiconductor region, in surface regions of the semiconductor substrate at the first main surface thereof in the termination region, the second-conductivity-type voltage withstanding regions each concentrically surrounding the periphery of the active region. The second-conductivity-type voltage withstanding regions have an impurity concentration that is less than 1×10¹⁸/cm³. The second-conductivity-type voltage withstanding regions have a thickness in a range of 0.7 μm to 1.1 μm.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting a layout when a semiconductor device according to a first embodiment is viewed from a front side of a semiconductor substrate.

FIG. 2 is a cross-sectional view depicting a structure along cutting line A-A′ in FIG. 1.

FIG. 3 is a cross-sectional view depicting a state of the semiconductor device according to the first embodiment during manufacture.

FIG. 4 is a cross-sectional view depicting a state of the semiconductor device according to the first embodiment during manufacture.

FIG. 5 is a cross-sectional view depicting a state of the semiconductor device according to the first embodiment during manufacture.

FIG. 6 is a cross-sectional view depicting a state of the semiconductor device according to the first embodiment during manufacture.

FIG. 7 is a cross-sectional view depicting a state of the semiconductor device according to the first embodiment during manufacture.

FIG. 8 is a cross-sectional view depicting a state of the semiconductor device according to the first embodiment during manufacture.

FIG. 9 is a cross-sectional view depicting a structure of a semiconductor device according to a second embodiment.

FIG. 10 is a cross-sectional view depicting a structure of a semiconductor device according to a third embodiment.

FIG. 11 is a cross-sectional view depicting a structure of a semiconductor device according to a fourth embodiment.

FIG. 12 is a characteristics diagram showing results of simulation of a relationship between breakdown voltage and a first interval between a main pn junction and a FLR closest to the chip center in the example.

FIG. 13 is a characteristics diagram showing results of simulation of a relationship between an impurity concentration of FLRs in an experimental example and breakdown voltage.

FIG. 14 is a characteristics diagram showing results of simulation of a relationship between the breakdown voltage and an increase amount of a second interval between first and second FLRs from a chip center in the experimental example.

FIG. 15 is a characteristics diagram showing results of simulation of a relationship between the breakdown voltage and the increase amount of a third interval between the second and third FLRs from the chip center in the experimental example.

FIG. 16 is a characteristics diagram showing results of simulation of a relationship between FLR thickness and the breakdown voltage in the experimental example.

FIG. 17 is a characteristics diagram showing results of simulation of a relationship between the number of FLRs of the FLR structure in the experimental example and the breakdown voltage.

FIG. 18 is a cross-sectional view depicting a structure of a conventional silicon carbide semiconductor device.

FIG. 19 is a cross-sectional view depicting another structure of a conventional silicon carbide semiconductor device.

### DETAILED DESCRIPTION OF THE INVENTION

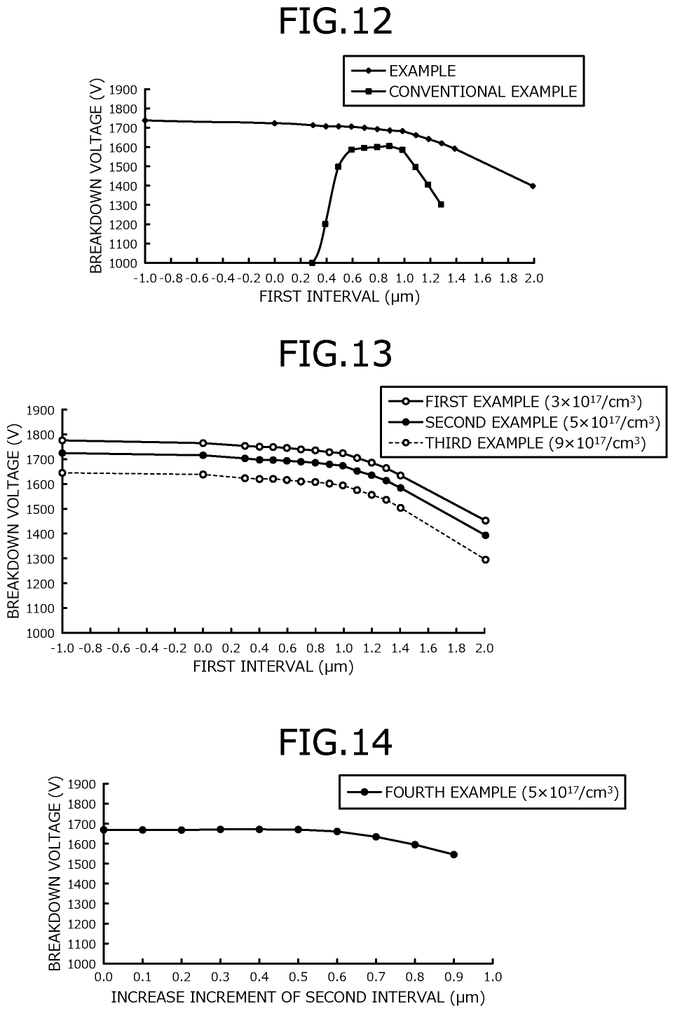

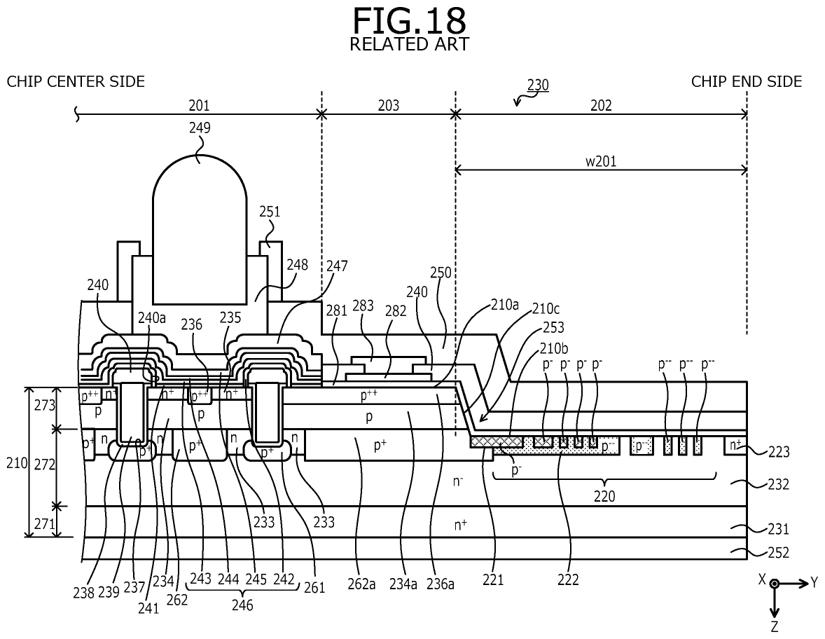

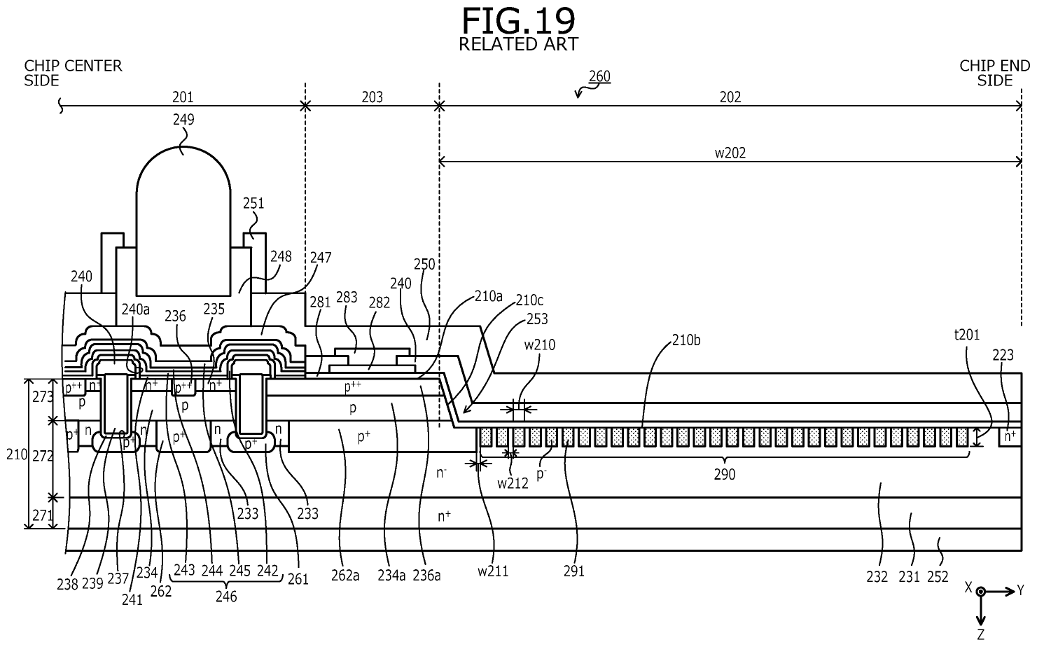

First, problems associated with the conventional techniques are discussed. In the conventional spatially modulated FLR structure 220 described above (refer to FIG. 18), due to ion implantation accuracy, variation of positions and/or impurity concentration of the FLRs 221, 222 configuring the FLR structure 220 occur and precision of the FLR structure 220 decreases, whereby reliability of the semiconductor device 230 may decrease. On the other hand, as described above, in the ordinary FLR structure 290 (refer to FIG. 19), the length w202 of the edge termination region 202 is long, adversely affecting cost. Further, a margin (allowance) of the interval w212 between an adjacent two of the FLRs 291 is small (refer to conventional example in FIG. 12) and reliability of the semiconductor device decreases.

Embodiments of a semiconductor device according to the present invention will be described in detail with reference to the accompanying drawings. In the present description and accompanying drawings, layers and regions prefixed with n or p mean that majority carriers are electrons or holes. Additionally, + or − appended to n or p means that the impurity concentration is higher or lower, respectively, than layers and regions without + or −. In the description of the embodiments below and the accompanying drawings, main portions that are identical will be given the same reference numerals and will not be repeatedly described.

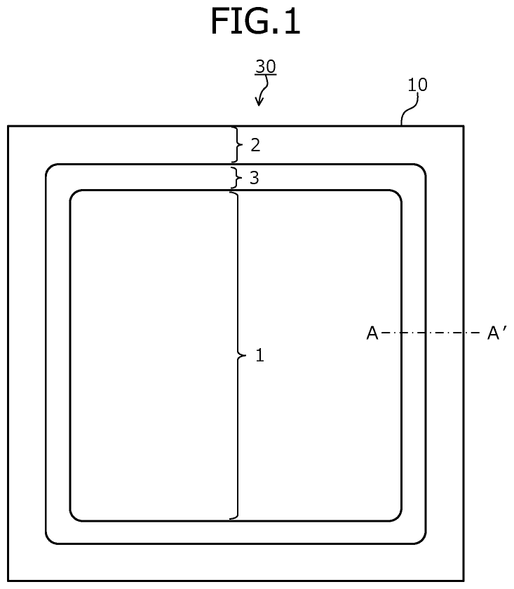

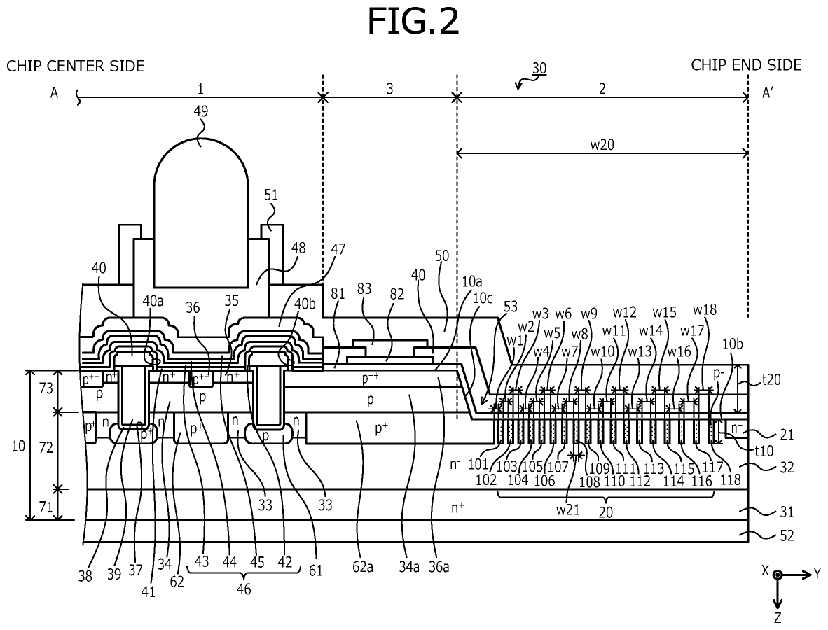

A structure of a semiconductor device according to a first embodiment is described. FIG. 1 is a plan view depicting a layout when the semiconductor device according to the first embodiment is viewed from a front side of a semiconductor substrate. FIG. 2 is a cross-sectional view depicting the structure along cutting line A-A′ in FIG. 1. A semiconductor device 30 according to the first embodiment depicted in FIGS. 1 and 2 is a vertical MOSFET having a trench gate structure (device element structure) in an active region 1 of a semiconductor substrate (semiconductor chip) 10 containing silicon carbide (SiC) and includes a field limiting ring (FLR) structure 20 as a voltage withstanding structure in an edge termination region 2 that surrounds a periphery of the active region 1.

The active region 1 is a region through which a main current (drift current) flows when the MOSFET (the semiconductor device 30) is ON. In the active region 1, multiple unit cells (constituent units of a device element) of the MOSFET each having a same structure are disposed. The active region 1, for example, has a substantially rectangular shape in a plan view thereof and is disposed in substantially a center (chip center) of the semiconductor substrate 10. The active region 1 is a region further on a chip inner side (chip center side) than is a chip-end (chip-end side) sidewall (side surface of an interlayer insulating film 40) of an outermost contact hole 40b, the chip-end sidewall of the outermost contact hole 40b being closest to the chip end, of the sidewalls of the outermost contact hole 40b. An intermediate region 3 between the active region 1 and the edge termination region 2 is in contact with the active region 1 and surrounds the periphery of the active region 1.

A boundary between the intermediate region 3 and the edge termination region 2 is a boundary between first and third surface portions 10a, 10c of the later-described semiconductor substrate 10. The edge termination region 2 is a region between the active region 1 and an end (the chip end) of the semiconductor substrate 10, the edge termination region 2 surrounds the periphery of the active region 1 via the intermediate region 3, and has a function of mitigating electric field of a front surface (first main surface) side of the semiconductor substrate 10 and sustaining a breakdown voltage. In the edge termination region 2, the FLR structure 20 is provided as a voltage withstanding structure in the semiconductor substrate 10 in the front side of the semiconductor substrate 10. The breakdown voltage is a voltage limit at which source-drain voltage does not increase further even when avalanche breakdown occurs at pn junctions and source-drain current increases.

In the active region 1, in the front side of the semiconductor substrate 10, the MOS gates are provided. The MOS gates are configured by a p-type base region 34, n⁺-type source regions 35, p⁺⁺-type contact regions 36, gate trenches 37, a gate insulating film 38, and the gate electrodes 39. Configuration is such that a portion (a later-described outer peripheral p-type base region 34a) at chip-end side (side closest to the chip end) of an outermost gate trench 37 that is closest to the chip end of the gate trenches 37 is free of the n⁺-type source regions 35. The semiconductor substrate 10 is formed by sequentially forming epitaxial layers 72, 73 constituting an n⁻-type drift region (first semiconductor region) 32 and the p-type base region (second semiconductor region) 34 by epitaxial growth on a front surface of an n⁺-type starting substrate 71 containing silicon carbide.

The semiconductor substrate 10 has a main surface having the p-type epitaxial layer 73, assumed as the front surface, and another main surface having the n⁺-type starting substrate 71, assumed as a back surface (second main surface). The n⁺-type starting substrate 71 is an n⁺-type drain region 31. A portion of the p-type epitaxial layer 73 in the edge termination region 2 is removed by etching and a drop 53 is formed at the front surface of the semiconductor substrate 10. With the drop 53 as a boundary, the front surface of the semiconductor substrate 10 is recessed toward the n⁺-type drain region 31 at a portion (second surface portion) 10b thereof in the edge termination region 2 as compared to a portion (first surface portion) 10a thereof in the active region 1 and the intermediate region 3.

The second surface portion 10b of the front surface of the semiconductor substrate 10 is an exposed surface of the n⁻-type epitaxial layer 72 exposed by the removal of the p-type epitaxial layer 73. Device elements of the active region 1 and the intermediate region 3 are separated from those of the edge termination region 2 by a portion (third surface portion: mesa edge of the drop 53) 10c connecting the first surface portion 10a and the second surface portion 10b of the front surface of the semiconductor substrate 10. A side surface (portion including a later-described outer peripheral p⁺⁺-type contact region 36a and the later-described outer peripheral p-type base region 34a) of the p-type epitaxial layer 73 is exposed at the third surface portion 10c of the front surface of the semiconductor substrate 10.

Along the third surface portion 10c of the front surface of the semiconductor substrate 10, a p⁺-type region (not depicted) may be provided so that the later-described outer peripheral p⁺⁺-type contact region 36a, the outer peripheral p-type base region 34a, and an outer peripheral p⁺-type region 62a are continuous. When the drop 53 is formed, a surface region of the n⁻-type epitaxial layer 72 beneath the p-type epitaxial layer 73 may be slightly removed with the p-type epitaxial layer 73. The gate trenches 37, in a depth direction Z, penetrate through the p-type epitaxial layer 73 from the first surface portion 10a of the front surface of the semiconductor substrate 10 and reach the n⁻-type epitaxial layer 72.

The gate trenches 37, for example, extend in a striped pattern in a direction (here, a first direction X) parallel to the front surface of the semiconductor substrate 10, and reach the intermediate region 3. The gate electrodes 39 are provided in the gate trenches 37, via the gate insulating film 38. The p-type base region 34 is a portion of the p-type epitaxial layer 73 excluding the n⁺-type source regions 35 and the p⁺⁺-type contact regions 36. The p-type base region 34 extends toward the chip end (the chip end side) from the active region 1 and reaches the third surface portion 10c of the front surface of the semiconductor substrate 10.

The p-type base region 34 is provided in an entire area of the active region 1 and the intermediate region 3. An outer peripheral portion (hereinafter, outer peripheral p-type base region) 34a of the p-type base region 34 surrounds the periphery of the active region 1 in a substantially rectangular shape. The outer peripheral p-type base region 34a is a portion of the p-type base region 34, closer to the chip end in the first direction X (longitudinal direction of the gate trenches 37) than are the n⁺-type source regions 35 and is a portion closer to the chip end than is the outermost gate trench 37 in a second direction Y (lateral direction of the gate trenches 37) that is parallel to the front surface of the semiconductor substrate 10 and orthogonal to the first direction X.

The n⁺-type source regions 35 and the p⁺⁺-type contact regions 36 are selectively provided between the first surface portion 10a of the front surface of the semiconductor substrate 10 and the p-type base region 34, in contact with the p-type base region 34 and are exposed at the first surface portion 10a of the front surface of the semiconductor substrate 10. Here, being exposed at the first surface portion 10a of the front surface of the semiconductor substrate 10 means that the n⁺-type source regions 35 and the p⁺⁺-type contact regions 36 are in contact with a later-described NiSi film 41 by contact holes 40a of the later-described interlayer insulating film 40.

The n⁺-type source regions 35 are in contact with the gate insulating film 38, at sidewalls of the gate trenches 37. The p⁺⁺-type contact regions 36 are disposed further apart from the gate trenches 37 than are the n⁺-type source regions 35. The p-type base region 34, the n⁺-type source regions 35, and the p⁺⁺-type contact regions 36 extend between the gate trenches 37 adjacent to one another, for example, in the longitudinal direction of the gate trenches 37 (not depicted). The p⁺⁺-type contact regions 36 may be scattered in the first direction X.

Further, the p⁺⁺-type contact regions 36, in an entire area between the first surface portion 10a of the front surface of the semiconductor substrate 10 and the outer peripheral p-type base region 34a, are provided in contact with the outer peripheral p-type base region 34a. Hereinafter, a portion of the p⁺⁺-type contact regions 36 between the first surface portion 10a of the front surface of the semiconductor substrate 10 and the outer peripheral p-type base region 34a is assumed as the outer peripheral p⁺⁺-type contact region 36a. The outer peripheral p⁺⁺-type contact region 36a is in contact with the gate insulating film 38 at a chip-end sidewall of the outermost gate trench 37, the chip-end sidewall of the outermost gate trench 37 being closest to the chip end of the sidewalls of the outermost gate trench 37.

The outer peripheral p⁺⁺-type contact region 36a is exposed at the first surface portion 10a of the front surface of the semiconductor substrate 10. Here, being exposed at the first surface portion 10a of the front surface of the semiconductor substrate 10 means that the outer peripheral p⁺⁺-type contact region 36a is in contact with the NiSi film 41 by the outermost contact hole 40b. The outer peripheral p⁺⁺-type contact region 36a has a function of leading out holes accumulated in the edge termination region 2 due to switching, etc. of the MOSFET, the holes being led out to a source electrode, via the outer peripheral p⁺-type region 62a and the outer peripheral p-type base region 34a, when the MOSFET turns OFF.

The p⁺⁺-type contact regions 36 and the outer peripheral p⁺⁺-type contact region 36a may be omitted. In this instance, instead of the p⁺⁺-type contact regions 36 and the outer peripheral p⁺⁺-type contact region 36a, the p-type base region 34 and the outer peripheral p-type base region 34a each reach and are exposed at the front surface of the semiconductor substrate 10. In the semiconductor substrate 10, the n⁻-type drift region 32 is provided between and in contact with the p-type base region 34, the outer peripheral p-type base region 34a, and the n⁺-type drain region 31 (the n⁺-type starting substrate 71).

N-type current spreading regions 33 and first and second p⁺-type regions 61, 62 are selectively provided between the p-type base region 34, the outer peripheral p-type base region 34a, and the n⁻-type drift region 32. Lower surfaces of the n-type current spreading regions 33 and the first and the second p⁺-type regions 61, 62 are disposed at deep positions closer to the n⁺-type drain region 31 than are bottoms of the gate trenches 37. Upper surfaces of the n-type current spreading regions 33 and the second p⁺-type regions 62 are in contact with the p-type base region 34. The n-type current spreading regions 33 and the first and the second p⁺-type regions 61, 62 extend in a linear shape of a length substantially equal to that of the gate trenches 37, in the longitudinal direction of the gate trenches 37.

The n-type current spreading regions 33 are a so-called current spreading layer (CSL) that reduces carrier spreading resistance. The n-type current spreading regions 33 are in contact with the first and the second p⁺-type regions 61, 62 between the gate trenches 37 adjacent to one another. The n-type current spreading regions 33 may extend in the intermediate region 3 from the active region 1. The n-type current spreading regions 33 may be omitted. In this instance, the n⁻-type drift region 32 extends to the front side of the semiconductor substrate 10 and is in contact with the p-type base region 34.

The first and the second p⁺-type regions 61, 62 have a function of mitigating electric field applied to the gate insulating film 38 at the bottoms of the gate trenches 37. Depths of the first and the second p⁺-type regions 61, 62 may be suitably set. For example, the first and the second p⁺-type regions 61, 62 may terminate in the n-type current spreading regions 33 and peripheries thereof may be surrounded by the n-type current spreading regions 33, or may reach positions of a same depth as the n-type current spreading regions 33 in the depth direction Z, or may reach deep positions closer to the n⁺-type drain region 31 than are the n-type current spreading regions 33 to be in contact with the n⁻-type drift region 32.

The first p⁺-type regions 61 are disposed apart from the p-type base region 34 and face the bottoms of the gate trenches 37 in the depth direction Z. The first p⁺-type regions 61 may reach the bottoms of the gate trenches 37. While the first p⁺-type regions 61 may have a floating potential, other p⁺-type regions (not depicted) may be disposed at predetermined locations between the first and the second p⁺-type regions 61, 62 or a portion of the first p⁺-type regions 61 may extend in a direction toward the second p⁺-type regions 62, whereby the first p⁺-type regions 61 may be electrically connected to the second p⁺-type regions 62 at predetermined locations and fixed to the potential of the source electrode.

Between the gate trenches 37 adjacent to one another, the second p+-type regions 62 are disposed apart from the first p⁺-type regions 61 and the gate trenches 37 and in the depth direction Z, are adjacent to the p-type base region 34. Further, one of the second p⁺-type regions 62 (hereinafter, the outer peripheral p⁺-type region (second-conductivity-type high-concentration region) 62a) is disposed closer to the chip end than is the outermost gate trench 37, is apart from the first p⁺-type regions 61 and the outermost gate trench 37, and is adjacent to the outer peripheral p-type base region 34a in the depth direction Z. The outer peripheral p⁺-type region 62a extends from the active region 1, in a direction toward the chip end and is provided in an entire area of the intermediate region 3.

The outer peripheral p⁺-type region 62a surrounds the periphery of the active region 1 in a substantially rectangular shape and is continuous with ends of all the first and the second p⁺-type regions 61, 62. The outer peripheral p⁺-type region 62a extends from the intermediate region 3, is closer to the chip end than is the drop 53, and is exposed at the second surface portion 10b of the front surface of the semiconductor substrate 10. The outer peripheral p⁺-type region 62a may be exposed at the third surface portion 10c of the front surface of the semiconductor substrate 10. Being exposed at the second and the third surface portions 10b, 10c of the front surface of the semiconductor substrate 10 means being in contact with a later-described field oxide film 81 on the second and the third surface portions 10b, 10c.

In an instance in which the first and the second p⁺-type regions 61, 62 (including the outer peripheral p⁺-type region 62a) and later-described FLRs 101, 102, 103, 104, 105, 106, 107, 108, 109, 110, 111, 112, 113, 114, 115, 116, 117, 118 are formed concurrently, an impurity concentration of the first and the second p⁺-type regions 61, 62 (including the outer peripheral p⁺-type region 62a), for example, is less than about 1×10¹⁸/cm³ or preferably may be, for example, in a range of about 3×10¹⁷/cm³ to 9×10¹⁷/cm³. Further, a thickness (length in the depth direction Z) of the second p⁺-type regions 62 is, for example, in a range of about 0.7 μm to 1.1 μm, whereby the second p⁺-type regions 62 (including the outer peripheral p⁺-type region 62a) may be formed concurrently with the later-described FLRs 101 to 118.

A portion of the n⁻-type epitaxial layer 72 excluding the n-type current spreading regions 33, the first and the second p⁺-type regions 61, 62 (as well as the outer peripheral p⁺-type region 62a), the later-described FLRs 101 to 118, and a later-described n⁺-type channel stopper region 21 constitutes the n⁻-type drift region 32. Between these regions and the n⁺-type drain region 31, the n⁻-type drift region 32 is provided. The n⁻-type drift region 32 extends from the active region 1 to the chip end and is exposed at an end (side surface of the semiconductor substrate 10) of the semiconductor substrate 10.

The interlayer insulating film 40 is provided in an entire area of the front surface of the semiconductor substrate 10 and covers all the gate electrodes 39.

In the active region 1, the contact holes 40a, 40b penetrating through the interlayer insulating film 40 in the depth direction Z are provided in the interlayer insulating film 40. In the contact holes 40a, the n⁺-type source regions 35 and the p⁺⁺-type contact regions 36 are exposed. The contact hole 40b, for example, is provided in a substantially rectangular shape surrounding the periphery of the active region 1. In the contact hole 40b, the outer peripheral p⁺⁺-type contact region 36a is exposed.

In the intermediate region 3 and the edge termination region 2, the first to third surface portions 10a to 10c of the front surface of the semiconductor substrate 10, at an entire area thereof closer to the chip end than is the outer peripheral p⁺⁺-type contact region 36a, are covered by an insulating layer constituted by the field oxide film 81 and the interlayer insulating film 40 that are sequentially stacked. Without provision of a field plate (conductive film), in the intermediate region 3 and the edge termination region 2, the first to third surface portions 10a to 10c of the front surface of the semiconductor substrate 10 have an area that is closer to the chip end than is the outer peripheral p⁺⁺-type contact region 36a and that is entirely in contact with the field oxide film 81.

In the intermediate region 3, a gate polysilicon (poly-Si) wiring layer 82 and a gate metal wiring layer 83 constituting a gate runner are sequentially stacked on the field oxide film 81, at a portion thereof closer to the chip end than is the outer peripheral p⁺⁺-type contact region 36a. The gate polysilicon wiring layer 82 and the gate metal wiring layer 83 face ends of the gate trenches 37 in the depth direction Z, are electrically connected to the gate electrodes 39 at the ends of the gate trenches 37, and electrically connect the gate electrodes 39 and a gate pad (not depicted).

In surface regions at the second surface portion 10b of the front surface of the semiconductor substrate 10, in the n⁻-type epitaxial layer 72, multiple p⁻-type regions (FLRs (second-conductivity-type voltage withstanding regions), hatched portions) having a floating potential and configuring the FLR structure 20 are selectively provided, and the n⁺-type channel stopper region 21 is selectively provided apart from the multiple p⁻-type regions and closer to the chip end than are the multiple p⁻-type regions. The FLR structure 20 may be configured by at least 16 FLRs (herein, 18 are assumed, indicated by reference numerals 101 to 118 from nearest the chip center). The FLRs 101 to 118 and the n⁺-type channel stopper region 21 are exposed at the second surface portion 10b of the front surface of the semiconductor substrate 10.

The FLRs 101 to 118 are disposed closer to the chip end than is the outer peripheral p⁺-type region 62a and the FLRs 101 to 118 are disposed apart from one another between the outer peripheral p⁺-type region 62a and the n⁺-type channel stopper region 21, and concentrically surround the periphery of the active region 1 via the intermediate region 3. Of the FLRs 101 to 118, an innermost FLR 101 closest to the chip center faces the outer peripheral p⁺-type region 62a in a direction parallel to the front surface of the semiconductor substrate 10. Of the FLRs 101 to 118, an outermost FLR 118 closest to the chip end faces the n⁺-type channel stopper region 21 in a direction parallel to the front surface of the semiconductor substrate 10.

Peripheries of all the FLRs 101 to 118 are surrounded by the n⁻-type drift region 32. Between the innermost FLR 101 and the outer peripheral p⁺-type region 62a, between adjacent FLRs of the FLRs 101 to 118, and between the outermost FLR 118 and the n⁺-type channel stopper region 21, the n⁻-type drift region 32 is disposed. Pn junctions between the FLRs 101 to 118 and the n⁻-type drift region 32 bear high voltage applied to the edge termination region 2 when the MOSFET is OFF and sustain a predetermined breakdown voltage of the edge termination region 2.

Preferably, a first interval w1 between the innermost FLR 101 and the outer peripheral p⁺-type region 62a, for example, may be at most about 1.2 μm. The first interval w1 between the innermost FLR 101 and the outer peripheral p⁺-type region 62a is an interval between a pn junction (main pn junction) between the outer peripheral p⁺-type region 62a and the n⁻-type drift region 32, and the innermost (first from the chip center) FLR 101. The first interval w1 between the innermost FLR 101 and the outer peripheral p⁺-type region 62a is set to be narrower the greater the breakdown voltage of the semiconductor device 30 is reduced.

The innermost FLR 101 may be provided at a position to be in contact with the outer peripheral pt-type region 62a (w1=0.0 μm), or may be provided at a position to overlap and be in contact with the outer peripheral pt-type region 62a (w1<0.0 μm). For example, in an instance in which the breakdown voltage of the semiconductor device 30 is 600V, the innermost FLR 101 is disposed in contact with the outer peripheral pt-type region 62a. In an instance in which the innermost FLR 101 is in contact with the outer peripheral pt-type region 62a, second to eighteenth intervals w2, w3, w4, w5, w6, w7, w8, w9, w10, w11, w12, w13, w14, w15, w16, w17, w18 respectively between adjacent FLRs of the FLRs 101 to 118 are set to be wider compared to in an instance in which the innermost FLR 101 is apart from the outer peripheral pt-type region 62a.

The second to the eighteenth intervals w2 to w18 respectively between adjacent FLRs of the FLRs 101 to 118 are set to be narrower the greater the breakdown voltage of the semiconductor device 30 is to be reduced. The second to the eighteenth intervals w2 to w18 respectively between adjacent FLRs of the FLRs 101 to 118 are disposed in ascending order of width in a direction approaching the chip end, the widths of the second to the eighteenth intervals w2 to w18 uniformly increasing relative to one another by a predetermined increase amount (width in the direction of the normal) the closer said second to the eighteenth interval w2 to w18 is disposed to the chip end. The direction of the normal is a direction from the active region 1 (chip center side) to the chip end. For example, in an instance in which the increase amount is 0.1 μm, a j-th interval wj between an adjacent two of the FLRs 102 to 118 is a value obtained by adding 0.1 μm to an adjacent k-th interval wk between an adjacent two of the FLRs 101 to 117 closer to the chip center (j=2˜18, k=j−1).

In an instance in which the innermost FLR 101 is in contact with the outer peripheral p⁺-type region 62a, arrangement from the innermost FLR 101 to the FLR 104 that is fourth from the chip center may be under the following conditions. The second interval w2 between the innermost FLR 101 and the FLR 102 that is second from the chip center, for example, may be set to be at most about 2.1 μm. The third interval w3 that is between the FLR 102 that is second from the chip center and the FLR 103 that is third from the chip center, for example, may be set to be at most about 3.1 μm or preferably, may be set to be at most about 1.0 μm.

In an instance in which the third interval w3 that is between the FLR 102 that is second from the chip center and the FLR 103 that is third from the chip center is set to be at most about 1.0 μm, the fourth interval w4 between the FLR 103 that is third from the chip center and the FLR 104 that is fourth from the chip center, for example, may be set to be at most about 2.0 μm. In an instance in which the innermost FLR 101 and the outer peripheral pt-type region 62a are apart from each other, the fifth to the eighteenth intervals w5 to w18 between the FLRs 104 to 118 (fourth and subsequent FLRs from the center) may be set to be wider than the first interval w1 between the innermost FLR 101 and the outer peripheral pt-type region 62a.

All the FLRs 101 to 118 are formed having the same configuration, substantially a same width (direction of the normal) w21, substantially a same thickness (length in the depth direction Z) t10, and substantially the same impurity concentration. The width w21 of each of the FLRs 101 to 118, for example, is about ½ of the width w210 of each of the FLRs 291 of the conventional FLR structure 290 (refer to FIG. 19) and, for example, is in a range of about 5 μm to 15 μm (breakdown voltage of 1200V). The thickness t10 of each of the FLRs 101 to 118, for example, is about 2 times the thickness t201 of each of the FLRs 291 of the conventional FLR structure 290 (refer to FIG. 19) and, for example, is in a range of about 0.7 μm to 1.1 μm.

The thickness t10 of each of the FLRs 101 to 118 is set to be thicker than the thickness t201 of each of the FLRs 291 of the conventional FLR structure 290, whereby electric field applied to the FLRs 101 to 118 when the semiconductor device 30 is OFF may be mitigated as compared to in the conventional FLR structure 290. Therefore, the width w21 of each of the FLRs 101 to 118, the first interval w1 between the innermost FLR 101 and the outer peripheral pt-type region 62a, and the second to the eighteenth intervals w2 to w18 respectively between adjacent FLRs of the FLRs 101 to 118 may be narrower compared to those in the conventional FLR structure 290.

A length (length from the intermediate region 3 to the chip end) w20 of the edge termination region 2 is about ½ of the length w202 of the edge termination region 202 for the same number (18) of FLRs (the FLRs 291) disposed therein of the conventional FLR structure 290 (refer to FIG. 19), and about the same (for example, in an instance of the breakdown voltage of 1200V, a range of about 100 μm to 200 μm) as the length w201 of the edge termination region 202 in which the spatially modulated FLR structure 220 is disposed (refer to FIG. 18). Each of the FLRs 101 to 118 has substantially the same cross-sectional area as that of each of the FLRs 291 of the conventional FLR structure 290 and a substantially rectangular shape vertically longer in the depth direction Z than that of each of the FLRs 291, in cross-sectional views thereof.

In this manner, all the FLRs 101 to 118 have a shape vertically longer in the depth direction Z in a cross-sectional view, whereby even when charge accumulates in an insulating layer (the field oxide film 81, the interlayer insulating film 40, and a first protective film 50) on the second surface portion 10b of the front surface of the semiconductor substrate 10 due to the MOSFET being continuously ON for long periods, adverse effects of the charge are suppressed. The FLRs 102 to 118 (the second and subsequent FLRs from the chip center) may be wider than the width w21 of the innermost FLR 101. In this instance, all the FLRs 102 to 118 (the second and subsequent FLRs from the chip center) have substantially the width w21.

An adverse effect due to charge in the insulating layer is suppression of the spreading of a depletion layer in the n⁻-type drift region 32 in the edge termination region 2 due to positive charge in the insulating layer when the insulating layer is positively charged. Further, when the insulating layer is negatively charged, potential in the n⁻-type drift region 32 in the edge termination region 2 is pulled toward the chip end due to negative charge in the insulating layer and easily spreads to the chip outer side. Adverse effects of charge accumulated in the insulating layer are suppressed, whereby breakdown voltage characteristics of the FLR structure 20 may be stabilized.

The impurity concentration of each of the FLRs 101 to 118 is lower than the impurity concentration of each of the FLRs 291 configuring the conventional FLR structure 290 (refer to FIG. 19) and, for example, is less than about 1×10¹⁸/cm³. Preferably, the impurity concentration of each of the FLRs 101 to 118, for example, may be in a range of about 3×10¹⁷/cm³ to 9×10¹⁷/cm³ or, for example, may be about 5×10¹⁷/cm³. The lower is the breakdown voltage of the semiconductor device 30, the higher the impurity concentration of each of the FLRs 101 to 118 may be set.

The impurity concentration of each of the FLRs 101 to 118 is set to be lower than the impurity concentration of each of the FLRs 291 configuring the conventional FLR structure 290, whereby electric field applied to the FLRs 101 to 118 when the semiconductor device 30 is OFF may be mitigated as compared to in the conventional FLR structure 290. Therefore, the width w21 of each of the FLRs 101 to 118, the first interval w1 between the innermost FLR 101 and the outer peripheral p⁺-type region 62a, and the second to the eighteenth intervals w2 to w18 respectively between adjacent FLRs of the FLRs 101 to 118 may be narrower compared to those in the conventional FLR structure 290.

The FLRs 101 to 118 may be formed concurrently with the first and the second p⁺-type regions 61, 62 (including the outer peripheral p⁺-type region 62a). The FLRs 101 to 118 may reach deep positions closer to the n⁺-type drain region 31 than are the first and the second p⁺-type regions 61, 62 (including the outer peripheral p⁺-type region 62a). In this instance, the second to the eighteenth intervals w2 to w18 respectively between adjacent FLRs of the FLRs 101 to 118 may be set to be wider compared to an instance in which the FLRs 101 to 118 are at positions of the same depth toward the n⁺-type drain region 31 as the first and the second p⁺-type regions 61, 62.

The n⁺-type channel stopper region 21 is provided closer to the chip end than is the FLR structure 20 and is apart from the FLR structure 20. The n⁺-type channel stopper region 21 is exposed at the end of the semiconductor substrate 10. The n⁺-type channel stopper region 21 is provided, whereby compared to an instance in which the n⁺-type channel stopper region 21 is omitted, a depletion layer that spreads in the n⁻-type drift region 32, from the active region 1, in a direction toward the chip end when the MOSFET is OFF may be suppressed. A channel stopper electrode (not depicted) is not provided.

In an instance in which a p⁺-type channel stopper region (not depicted) is provided instead of the n⁺-type channel stopper region 21, effects similar to those by the n⁺-type channel stopper region 21 are obtained. The n⁺-type channel stopper region 21 may be omitted in an instance in which conditions of the FLR structure 20 are set so that a depletion layer that spreads in the n⁻-type drift region 32, from the active region 1, in a direction toward the chip end when the MOSFET is OFF, does not reach the chip end even when negative charge accumulates in the insulating layer on the second surface portion 10b of the front surface of the semiconductor substrate 10.

The second and the third surface portions 10b, 10c of the front surface of the semiconductor substrate 10, as described above, are covered by the insulating layer constituted by the field oxide film 81 and the interlayer insulating film 40 that are sequentially stacked. The insulating layer, at the second surface portion 10b of the front surface of the semiconductor substrate 10, covers the FLRs 101 to 118, the n⁺-type channel stopper region 21, and a portion of the n⁻-type drift region 32 between these regions. The first protective film 50 (passivation film) covers an entire area of the front surface of the semiconductor substrate 10 and is a surface protective film for protecting the front surface of the semiconductor substrate 10.

A total thickness t20 of the field oxide film 81, the interlayer insulating film 40, and the first protective film 50 is at least equal to a thickness of the gate insulating film 38, may be thickness that may withstand applied voltage and, for example, in an instance in which the breakdown voltage of the MOSFET is 1700V, the total thickness t20 is at least about 1.7 μm. A nickel silicide (NixSiy, where, x, y are integers, hereinafter, collectively “NiSi”) film 41 is in ohmic contact with the semiconductor substrate 10 and electrically connected to the n⁺-type source regions 35 and the p⁺⁺-type contact regions 36, in the contact holes 40a, 40b.

The NiSi film 41 is electrically connected to the outer peripheral p⁺⁺-type contact region 36a, in the contact hole 40b. In an instance in which the p⁺⁺-type contact regions 36 and the outer peripheral p⁺⁺-type contact region 36a are omitted, instead of the p⁺⁺-type contact regions 36 and the outer peripheral p⁺⁺-type contact region 36a, the p-type base region 34 and the outer peripheral p-type base region 34a are exposed in the contact holes 40a, 40b, respectively, and are electrically connected to the NiSi film 41. A barrier metal 46 is provided along the surfaces of the interlayer insulating film 40 and the NiSi film 41, in an entire area thereof in the active region 1.

The barrier metal 46 has a function of preventing mutual reaction between metal films of the barrier metal 46 or between regions facing each other across the barrier metal 46. The barrier metal 46, for example, may have a stacked structure in which a first titanium nitride (TiN) film 42, a first titanium (Ti) film 43, a second TiN film 44, and a second Ti film 45 are sequentially stacked. The first TiN film 42 covers an entire area of the surface of the interlayer insulating film 40 in the active region 1. The first Ti film 43 is provided on an entire area of the surfaces of the first TiN film 42 and the NiSi film 41.

The second TiN film 44 is provided on an entire area of the surface of the first Ti film 43. The second Ti film 45 is provided on an entire area of the surface of the second TiN film 44. An aluminum (Al) electrode film 47 is provided on an entire area of the surface of the second Ti film 45. The Al electrode film 47 is electrically connected to the n⁺-type source regions 35, the p⁺⁺-type contact regions 36, and the outer peripheral p⁺⁺-type contact region 36a via the barrier metal 46 and the NiSi film 41. The Al electrode film 47 and the barrier metal 46 terminate closer to the chip center than does the later-described gate metal wiring layer 83 of the intermediate region 3.

The Al electrode film 47, for example, may be an Al film, an aluminum-silicon (Al—Si) film, or an aluminum-silicon-copper (Al—Si—Cu) film having a thickness of about 5 μm. The Al electrode film 47, the barrier metal 46, and the NiSi film 41 function as the source electrode (first electrode). First ends of terminal pins 49 are bonded on the Al electrode film 47, via a metal plating film 48 and a soldering layer (not depicted). Second ends of the terminal pins 49 are bonded to a metal bar (not depicted) that is disposed facing the front surface of the semiconductor substrate 10.

Further, the second ends of the terminal pins 49 are exposed outside of a case (not depicted) in which the semiconductor substrate 10 is mounted and are electrically connected to an external device (not depicted). Terminal pins 49 are soldered to the metal plating film 48, in an upright state orthogonal to the front surface of the semiconductor substrate 10. The terminal pins 49 are round rod-shaped (cylindrical) wiring members having a predetermined diameter corresponding to the current capability of the MOSFET and are connected to an external ground potential (minimum potential). The terminal pins 49 are connection terminals that lead out potential of the Al electrode film 47 to an external destination.

The first and second protective films 50, 51, for example, are organic high-polymer material films with high heat resistance such as a polyimide. The first protective film 50 covers a portion of the surface of the Al electrode film 47 other than that of the metal plating film 48. The first protective film 50 extends to the chip end so as to cover the Al electrode film 47, the interlayer insulating film 40, and the gate metal wiring layer 83, and functions as a passivation film. A portion of the Al electrode film 47 exposed in a contact hole of the first protective film 50 constitutes a source pad. The second protective film 51 covers a boundary between the metal plating film 48 and the first protective film 50.

In the edge termination region 2, the n⁻-type epitaxial layer may be exposed at the front surface of the semiconductor substrate 10, or the front surface of the semiconductor substrate 10, may be continuously flat from the active region 1 to the chip end without the drop 53. A drain electrode (second electrode) 52 is in ohmic contact with an entire area of the back surface (back surface of the n⁺-type starting substrate 71) of the semiconductor substrate 10. On the drain electrode 52, for example, a drain pad (electrode pad, not depicted) is provided having a stacked structure in which a Ti film, a nickel (Ni) film, and a gold (Au) film are sequentially stacked.

The terminal pins 49 are bonded to the Al electrode film 47 of the front surface of the semiconductor substrate 10, and the drain pad of the back surface is bonded to a metal base plate of an insulated substrate, whereby the semiconductor substrate 10 has a double-sided cooling structure having a cooling structure on each main surface. Heat generated by the semiconductor substrate 10 is dissipated from fin portions of a cooling fin, via the metal base bonded to the drain pad on the back surface of the semiconductor substrate 10 and from the metal bar to which the terminal pins 49 of the front surface of the semiconductor substrate 10 are bonded.

Operation of the semiconductor device 30 according to the first embodiment is described. In a state in which voltage (forward voltage) that is positive with respect to the source electrode (the Al electrode film 47) is applied to the drain electrode 52, when voltage at least equal to the gate threshold voltage is applied to the gate electrodes 39, a channel (n-type inversion layer) is formed in portions of the p-type base region 34 along the gate trenches 37. As a result, current that passes through the channel from the n⁺-type drain region 31 and to the n⁺-type source regions 35 flows, whereby the MOSFET turns ON.

On the other hand, in a state in which forward voltage is applied between the source and drain, when voltage less than the gate threshold voltage is applied to the gate electrodes 39, in the active region 1, pn junctions between the first and the second p⁺-type regions 61, 62, the p-type base region 34, the n-type current spreading region 33, and the n⁻-type drift region 32 are reverse biased, whereby the current stops flowing and the MOSFET maintains an OFF state. At this time, the pn junctions are reverse biased, whereby a depletion layer spreads from the pn junctions and the breakdown voltage of the active region 1 is ensured.

Furthermore, when the MOSFET is OFF, the depletion layer that spreads from the above-described pn junctions of the active region 1 further spreads through the edge termination region 2, in the direction of the normal, toward the chip end due to pn junctions between the FLRs 101 to 118 and the n⁻-type drift region 32 of the edge termination region 2. A predetermined breakdown voltage based on the depletion layer width (width in a direction from the active region 1 to the chip end (direction of the normal of the FLRs 101 to 118 disposed concentrically)) and dielectric field strength of silicon carbide may be secured to an extent that the depletion layer spreads to the chip end, through the edge termination region 2.

Further, when the MOSFET is OFF, voltage that is negative with respect to the source electrode (the Al electrode film 47) is applied to the drain electrode 52, whereby current may be passed in a forward direction through a parasitic diode formed by pn junctions between the first and the second p⁺-type regions 61, 62, the p-type base region 34, the n-type current spreading regions 33, and the n⁻-type drift region 32. For example, in an instance in which the MOSFET is device for an inverter, this parasitic diode built into the semiconductor substrate 10 may be used as a freewheeling diode for protecting the MOSFET itself.

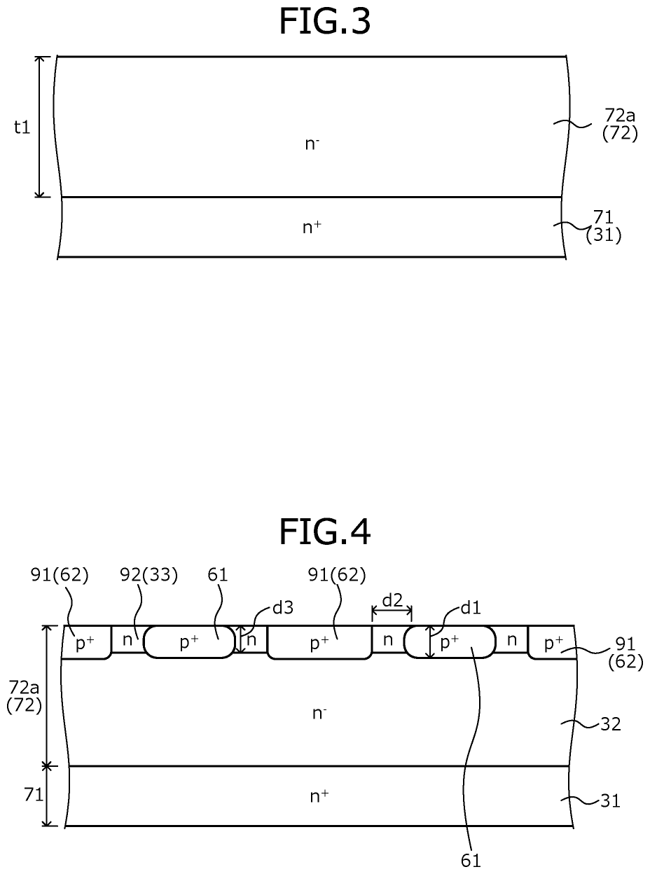

Next, a method of manufacturing the semiconductor device 30 according to the first embodiment is described. FIGS. 3, 4, 5, 6, 7, and 8 are cross-sectional views depicting states of the semiconductor device according to the first embodiment during manufacture. In FIGS. 3 to 8, the active region 1 is depicted, refer to FIG. 2 for the edge termination region 2 and the intermediate region 3. Here, an instance in which parts of the edge termination region 2 and the intermediate region 3 are formed concurrently with parts having the same impurity concentration and the same depth formed in the active region 1 is described as an example.

First, as depicted in FIG. 3, the n⁺-type starting substrate (starting wafer) 71 containing silicon carbide is prepared. Next, on the front surface of the n⁺-type starting substrate 71, an n⁻-type epitaxial layer 72a (72) doped with a lower concentration of nitrogen than is the n⁺-type starting substrate 71 is epitaxially grown. The n⁻-type epitaxial layer 72 has a thickness t1 that is, for example, about 30 μm when the breakdown voltage is 3300V and, for example, about 10 μm when the breakdown voltage is 1200V.

Next, as depicted in FIG. 4, in the active region 1, the first p⁺-type regions 61 and p⁺-type regions 91 constituting portions of the second p⁺-type regions 62 are formed in surface regions of the n⁻-type epitaxial layer 72 by photolithography and, for example, ion implantation of a p-type impurity such as Al. At this time, in surface regions of the n⁻-type epitaxial layer 72, the p⁺-type regions 91 constituting portions of the FLRs 101 to 118 and the outer peripheral p⁺-type region 62a are formed concurrently with the first p⁺-type regions 61.

Next, n-type regions 92 constituting portions of the n-type current spreading regions 33 are formed in surface regions of the n⁻-type epitaxial layer 72 by photolithography and, for example, ion implantation of an n-type impurity such as nitrogen (N). Ion implantations for forming the p⁺-type regions 61, 91 and the n-type regions 92 may be a multistage ion implantation divided into multiple sessions (multiple stages) in which a predetermined dose amount is ion-implanted under different conditions. A sequence in which the p⁺-type regions 61, 91 and the n-type regions 92 are formed may be interchanged.

In the active region 1, a distance d2 between an adjacent two of the p⁺-type regions 61, 91, for example, is about 1.5 μm. The p⁺-type regions 61, 91, for example, have a depth d1 of about 0.5 μm and as described above, an impurity concentration less than about 1.0×10¹⁸/cm³. The n-type regions 92 each has a depth d3 and an impurity concentration of, for example, about 0.4 μm and about 1.0×10¹⁷/cm³ to 5.0×10¹⁸/cm³, respectively.

Next, as depicted in FIG. 5, an n⁻-type epitaxial layer 72b (72) having a thickness t2 of, for example, about 0.5 μm and doped with, for example, an n-type impurity such as nitrogen is epitaxially grown on the n⁻-type epitaxial layer 72a, thereby increasing the n⁻-type epitaxial layer 72 to a predetermined thickness. The n⁻-type epitaxial layer 72 (72a, 72b) has an impurity concentration of, for example, about 3×10¹⁵/cm³.

Next, in the active region 1, p⁺-type regions 93 constituting portions of the second p⁺-type regions 62 are formed in the n⁻-type epitaxial layer 72b, by photolithography and ion implantation of a p-type impurity such as Al. Concurrently with the p⁺-type regions 93 at this time, the p⁺-type regions 93 constituting portions of the FLRs 101 to 118 and the outer peripheral p⁺-type region 62a are formed the n⁻-type epitaxial layer 72b.

Next, by photolithography and ion implantation of, for example, an n-type impurity such as nitrogen, n-type regions 94 constituting portions of the n-type current spreading regions 33 are formed in the n⁻-type epitaxial layer 72b. The p⁺-type regions 91, 93 facing one another in the depth direction Z are connected, whereby the second p⁺-type regions 62, the outer peripheral p⁺-type region 62a, and the FLRs 101 to 118 are formed. The n-type regions 92, 94 adjacent to one another in the depth direction Z are connected, thereby forming the n-type current spreading regions 33.

The thickness t10 of each of the FLRs 101 to 118 is set to be within the described range (for example, from about 0.7 μm to 1.1 μm) even when surface regions of the FLRs 101 to 118 are slightly removed after formation of the drop 53. Conditions such as the impurity concentrations for the p⁺-type regions 93 and the n-type regions 94, for example, are the same as those for the p⁺-type regions 91 and the n-type regions 92, respectively. A sequence in which the p⁺-type regions 93 and the n-type regions 94 are formed may be interchanged.

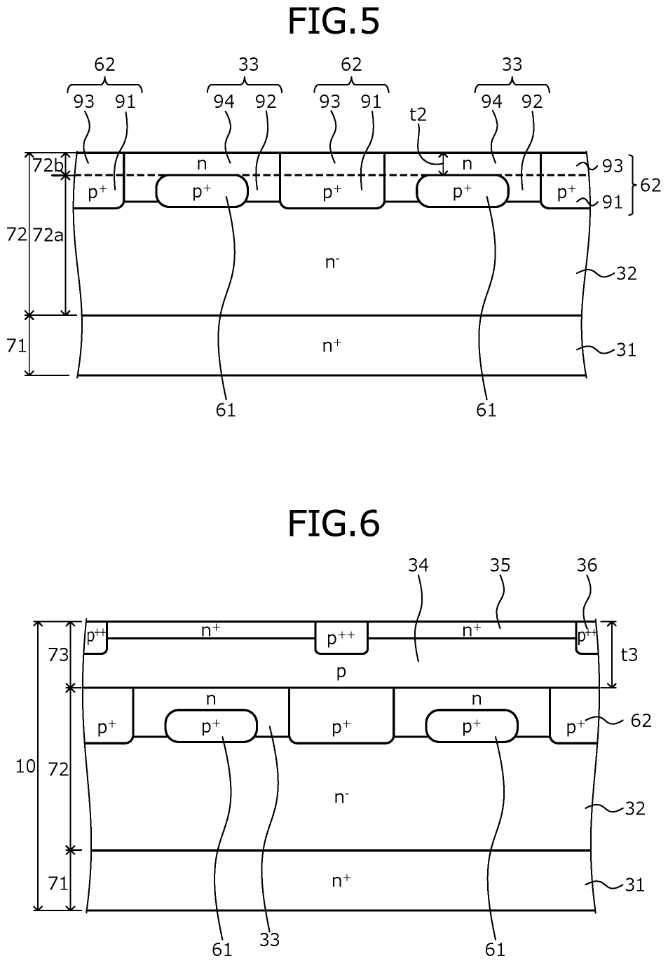

Next, as depicted in FIG. 6, for example, the p-type epitaxial layer 73 doped with a p-type impurity such as aluminum is epitaxially grown on the n⁻-type epitaxial layer 72. A thickness t3 and an impurity concentration of the p-type epitaxial layer 73 are, for example, about 1.3 μm and about 4×10¹⁷/cm³, respectively. By the processes up to here, the semiconductor substrate (semiconductor wafer) 10 in which the epitaxial layers 72, 73 are sequentially stacked on the n⁺-type starting substrate 71 is completed.

Next, a portion of the p-type epitaxial layer 73 in the edge termination region 2 is removed, whereby at the front surface of the semiconductor substrate 10, the drop 53 is formed whereby a portion (the second surface portion 10b) of the front surface in the edge termination region 2 is lower than a portion (the first surface portion 10a) of the front surface in the active region 1 and the intermediate region 3. At this time, etching in the edge termination region 2 may be stopped with exposure of the FLRs 101 to 118 at the front surface of the semiconductor substrate 10 being a (stop) condition.

The etching for forming the drop 53 is stopped immediately after the FLRs 101 to 118 are exposed at the front surface of the semiconductor substrate 10, whereby the FLRs 101 to 118 may be left having the predetermined thickness t10. Therefore, the predetermined breakdown voltage based on FLR structure design conditions may be stably obtained. In the edge termination region 2, the n⁻-type epitaxial layer 72 is exposed at the second surface portion 10b that newly constitutes a portion of the front surface of the semiconductor substrate 10.

The third surface portion 10c connecting the first surface portion 10a and the second surface portion 10b of the front surface of the semiconductor substrate 10, for example, may have form an obtuse angle (sloped surface) with respect to the first and the second surface portions 10a, 10b or may form a substantially right angle (vertical surface) therewith. The p-type epitaxial layer 73 is exposed at the third surface portion 10c of the front surface of the semiconductor substrate 10. The p-type epitaxial layer 73 and a surface region of the n⁻-type epitaxial layer 72 may be slightly removed by the etching for forming the drop 53.

Next, by photolithography and ion implantation under predetermined conditions, the n⁺-type source regions 35, the p⁺⁺-type contact regions 36, and the outer peripheral p⁺⁺-type contact region 36a are selectively formed in surface regions of the p-type epitaxial layer 73. In the edge termination region 2, the n⁺-type channel stopper region 21 is selectively formed, by ion implantation, in a surface region of the n⁻-type epitaxial layer 72 exposed at the second surface portion 10b of the front surface of the semiconductor substrate 10.

A sequence in which the n⁺-type source regions 35, the p⁺⁺-type contact regions 36, the outer peripheral p⁺⁺-type contact region 36a, and the n⁺-type channel stopper region 21 are formed may be interchanged. For example, the n⁺-type source regions 35 and the n⁺-type channel stopper region 21 may be formed concurrently. The n⁺-type source regions 35, the p⁺⁺-type contact regions 36, and the outer peripheral p⁺⁺-type contact region 36a may be formed before the drop 53 is formed.

Next, a heat treatment (hereinafter, activation annealing) for activating impurities ion-implanted in the epitaxial layers 72, 73 is performed. A single session of the activation annealing may be performed for all diffused regions collectively after formation thereof by ion implantation or the activation annealing may be performed for each formation of diffused regions by ion implantation. A temperature and period of the activation annealing, for example, may be about 1700 degrees C. and about 2 minutes, respectively.

Due to the activation annealing, in all the diffused regions formed by ion implantation (the n-type current spreading regions 33, the first and the second p⁺-type regions 61, 62, the outer peripheral p⁺-type region 62a, the n⁺-type source regions 35, the p⁺⁺-type contact regions 36, the outer peripheral p⁺⁺-type contact region 36a, the n⁺-type channel stopper region 21, and the FLRs 101 to 118), the impurities are activated and according to Gauss' law, impurity distribution occurs corresponding to the impurity concentrations and impurity diffusion coefficients.

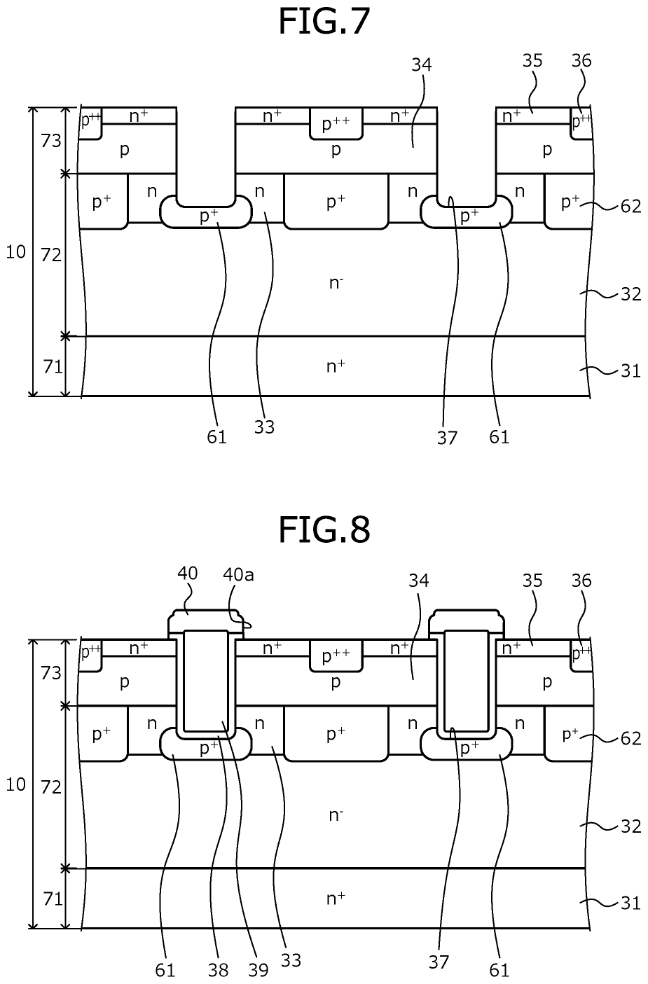

Next, as depicted in FIG. 7, by photolithography and etching, the gate trenches 37 that penetrate through the n⁺-type source regions 35 and the p-type base region 34, from the front surface of the semiconductor substrate 10, and face the first p⁺-type regions 61 in the n-type current spreading regions 33 are formed. The p-type base region 34 is a portion of the p-type epitaxial layer 73 left as a p-type and not subject to ion implantation. The drop 53 may be formed using the etching for forming the gate trenches 37.

Next, as depicted in FIG. 8, along the first surface portion 10a of the front surface of the semiconductor substrate 10 and inner walls (sidewalls and bottoms) of the gate trenches 37, the gate insulating film 38 is formed. The gate insulating film 38, for example, may be a thermal oxide film formed by thermally oxidizing the semiconductor surface by a temperature of about 1000 degrees C. under an oxygen (O₂) environment, or may be a deposited film such as a high temperature oxide (HTO).

Next, for example, a phosphorus (P) doped polysilicon layer is deposited (formed) on the front surface of the semiconductor substrate 10 so as to be embedded in the gate trenches 37. Next, the polysilicon layer is selectively removed, leaving only portions constituting the gate electrodes 39 in the gate trenches 37. Further, concurrently with leaving portions of the polysilicon layer as the gate electrodes 39, portions of the polysilicon layer may be left as the gate polysilicon wiring layer 82.

In an instance in which the gate electrodes 39 and the gate polysilicon wiring layer 82 are formed concurrently, after the gate insulating film 38 is formed but before the phosphorus-doped polysilicon layer is deposited, the field oxide film 81 is formed on the front surface of the semiconductor substrate 10, in the intermediate region 3 and the edge termination region 2. While not depicted in FIG. 2, the gate insulating film 38 may be left between the front surface of the semiconductor substrate 10 and the field oxide film 81.

Next, the interlayer insulating film 40 containing, for example, a borophosphosilicate glass (BPSG), a PSG, etc. and covering the gate electrodes 39 and the gate polysilicon wiring layer 82 in an entire area of the front surface of the semiconductor substrate 10, for example, may be formed having a thickness of 1 μm. Next, the contact holes 40a, 40b that penetrate the interlayer insulating film 40 and the gate insulating film 38 in the depth direction Z are formed by photolithography and etching.

In the contact holes 40a, the n⁺-type source regions 35 and the p⁺⁺-type contact regions 36 are exposed. In the contact hole 40b, the outer peripheral p⁺⁺-type contact region 36a is exposed. Further, concurrently with the formation of the contact holes 40a, 40b, a contact hole exposing the gate polysilicon wiring layer 82 is formed in the interlayer insulating film 40. Next, by a heat treatment, the interlayer insulating film 40 is planarized (reflow).

Next, in the active region 1, the first TiN film 42 that covers only the interlayer insulating film 40 is formed. Next, in the contact holes 40a, 40b, the NiSi film 41 that is in ohmic contact with the front surface of the semiconductor substrate 10 is formed. Further, a NiSi film in ohmic contact with the back surface of the semiconductor substrate 10 is formed as the drain electrode 52. The NiSi film is formed by causing a nickel film to react with the semiconductor substrate 10 by, for example, a heat treatment of a temperature of 970 degrees C.

Next, by a sputtering method, the first Ti film 43, the second TiN film 44, and the second Ti film 45 are sequentially stacked so as to cover the NiSi film 41 and the first TiN film 42, thereby forming the barrier metal 46 so as to cover an entire area of the active region 1. Next, the Al electrode film 47 is deposited on the second Ti film 45. Further, the gate pad (not depicted) is formed concurrently with the Al electrode film 47 and is formed on the interlayer insulating film 40, apart from the Al electrode film 47.

Further, the gate metal wiring layer 83 is formed on the gate polysilicon wiring layer 82, concurrently with the Al electrode film 47. Next, on the surface of the drain electrode 52, for example, a Ti film, an Ni film, and a gold (Au) film are sequentially stacked, thereby forming the drain pad (not depicted). Next, the first protective film 50 containing an organic high-polymer material such as a polyimide is formed in an entire area of the front surface of the semiconductor substrate 10, whereby the Al electrode film 47, the gate pad, and the gate metal wiring layer 83 are covered by the first protective film 50.

Next, in different openings formed by selectively removing the first protective film 50, the Al electrode film 47 (source pad) and the gate pad are exposed. Next, after a general plating pretreatment, the metal plating film 48 is formed in each of the openings of the first protective film 50 by a general plating process. Next, the metal plating films 48 are dried by a heat treatment (baking). Next, the second protective film 51 containing an organic high-polymer material such a polyimide is formed, covering the boundary between the metal plating film 48 and the first protective film 50.

Next, by a heat treatment (curing), the strength of the first and the second protective films 50, 51 is enhanced. Next, on each of the metal plating films 48, the terminal pins 49 are bonded by the soldering layer. On the gate pad (not depicted) as well, a wiring structure is formed in which terminal pins are bonded similarly to those on the Al electrode film 47. Thereafter, the semiconductor substrate 10 (semiconductor wafer) is diced (cut) into individual chips, whereby MOSFET (the semiconductor device 30) depicted in FIGS. 1 and 2 is completed.

As described above, according to the first embodiment, the FLR structure is included as a voltage withstanding structure in the edge termination region; the impurity concentration of the FLRs configuring the FLR structure is less than 1×10¹⁸/cm³ and is lower than the impurity concentration of the FLRs of the conventional FLR structure (refer to FIG. 19); and the thickness of the FLRs is in a range of 0.7 μm to 1.1 μm and is greater than the thickness of the FLRs of the conventional FLR structure. As a result, a margin of an interval between an adjacent two of the FLRs may be increased, whereby precision of the FLR structure increases and the reliability of the semiconductor device may be enhanced.

Further, according to the first embodiment, the impurity concentration of the FLRs is reduced, whereby electric field applied to the FLRs in the OFF state is mitigated. The thickness of the FLRs is increased, whereby the FLRs reach positions deep from the front surface of the semiconductor substrate and thus, adverse effects of external charge accumulated in a portion of the insulating layer on the front surface of the semiconductor substrate in the edge termination region are suppressed. As a result, the breakdown voltage of the edge termination region may be enhanced and therefore, compared to the conventional FLR structure, the length of the edge termination region may be reduced to about ½.

Further, according to the first embodiment, the voltage withstanding structure is set to be an ordinary FLR structure, whereby compared to an instance in which the voltage withstanding structure is set to be a spatially modulated FLR structure (refer to FIG. 18), design of the voltage withstanding structure is facilitated and effects of ion implantation accuracy are minimized. Further, as described above, the margin of the intervals between adjacent FLRs of the FLRs is increased, whereby compared to the conventional FLR structure, effects of ion implantation accuracy are minimized. Therefore, compared to an instance in which the spatially modulated FLR structure or the conventional FLR structure is formed as the voltage withstanding structure, fabrication (manufacturing) of the semiconductor device is facilitated.

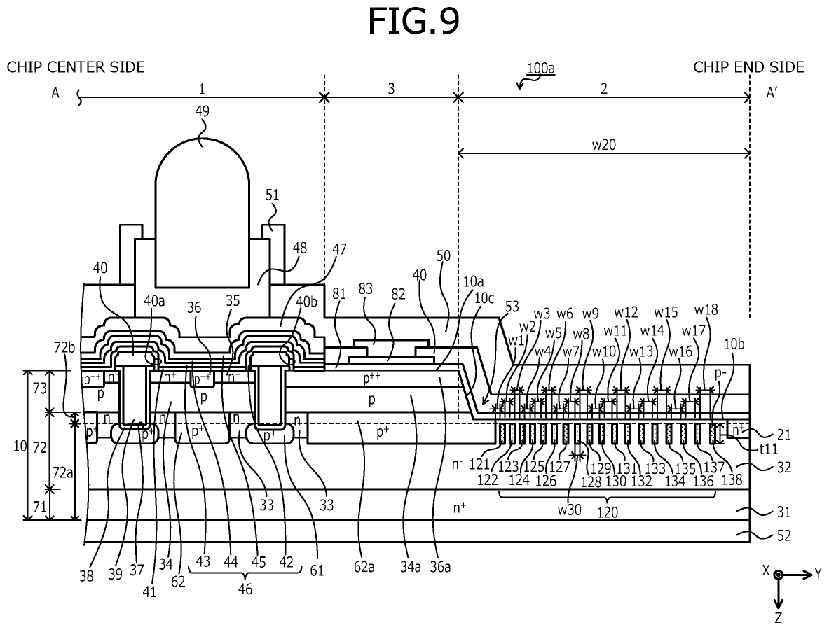

Next, a structure of a semiconductor device according to a second embodiment is described. FIG. 9 is a cross-sectional view depicting the structure of the semiconductor device according to the second embodiment. A layout when a semiconductor device 100a according to the second embodiment is viewed from the front surface of the semiconductor substrate 10 is the same as the layout depicted in FIG. 1. A FLR structure 120 of the semiconductor device 100a according to the second embodiment depicted in FIG. 9 differs from the FLR structure 20 of the semiconductor device 30 according to the first embodiment (refer to FIG. 2) in that FLRs (p⁻-type regions) 121, 122, 123, 124, 125, 126, 127, 128, 129, 130, 131, 132, 133, 134, 135, 136, 137, 138 configuring the FLR structure 120 are not exposed at the front surface of the semiconductor substrate 10.

In the second embodiment, the n⁻-type drift region 32 is provided between the second surface portion 10b of the front surface of the semiconductor substrate 10 and the FLRs 121 to 138. Upper ends (ends facing the second surface portion 10b of the front surface of the semiconductor substrate 10) of the FLRs 121 to 138 are apart from the second surface portion 10b of the front surface of the semiconductor substrate 10 by a distance in a range of, for example, about 0.1 μm to 0.2 μm and, for example, may be at a same depth position as upper ends of the first p⁺-type regions 61. Impurity concentration conditions for the FLRs 121 to 138 are the same as those for the FLRs 101 to 118 of the first embodiment.

A depth position of lower ends (ends facing the n⁺-type drain region 31) of the FLRs 121 to 138 is a same as that of the FLRs 101 to 118 of the first embodiment. Conditions for a thickness (length in the depth direction Z) t11 and a width w30 of the FLRs 121 to 138 are respectively the same as those for the thickness t10 and the width w21 of each of the FLRs 101 to 118 of the first embodiment. Conditions for the first interval w1 between the outer peripheral p⁺-type region 62a and the FLR 121 that, of the FLRs 121 to 138, is closest to the chip center and conditions for the second to the eighteenth intervals w2 to w18 between adjacent FLRs of the FLRs 121 to 138 are the same as those for the FLRs 101 to 118 in the first embodiment.

A method of manufacturing the semiconductor device 100a according to the second embodiment includes, in the method of manufacturing the semiconductor device 30 according to the first embodiment, similarly to the first p⁺-type regions 61 (refer to FIG. 5), forming the FLRs 121 to 138 only in the n⁻-type epitaxial layer 72a and forming the n⁻-type epitaxial layer 72b deposited on the n⁻-type epitaxial layer 72a. As a result, the FLRs 121 to 138 may be formed at a depth position that does not reach the surface of the n⁻-type epitaxial layer 72 (72a, 72b) constituting the second surface portion 10b of the front surface of the semiconductor substrate 10.

As described above, according to the second embodiment, effects similar to those of the first embodiment may be obtained. Further, according to the second embodiment, pn junctions between the FLRs and the n⁻-type drift region are disposed at deep positions apart from the second surface portion of the front surface of the semiconductor substrate and thus, adverse effects of external charge accumulated in a portion of the insulating layer on the front surface of the semiconductor substrate in the edge termination region are suppressed, the breakdown voltage characteristics of the FLR structure may be stabilized, and the reliability of the semiconductor device may be enhanced.

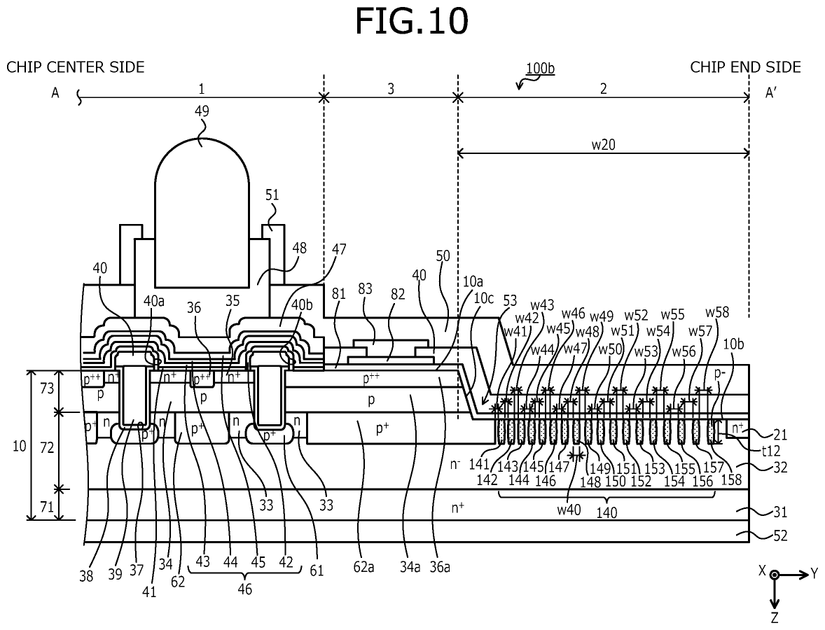

Next, a structure of a semiconductor device according to a third embodiment is described. FIG. 10 is a cross-sectional view depicting the structure of the semiconductor device according to the third embodiment. A layout when a semiconductor device 100b according to the third embodiment is viewed from the front surface of the semiconductor substrate 10 is the same as that depicted in FIG. 1. The semiconductor device 100b according to the third embodiment depicted in FIG. 10 differs from the semiconductor device 30 according to the first embodiment (refer to FIG. 2) in that FLRs (p⁻-type regions) 141, 142, 143, 144, 145, 146, 147, 148, 149, 150, 151, 152, 153, 154, 155, 156, 157, 158 configuring a FLR structure 140 each has, in a cross-sectional view thereof, a barrel-like shape with a relatively wide width w40 at a substantially center position in the depth direction Z.

In the third embodiment, the FLRs 141 to 158, for example, are formed having, in a cross-sectional view thereof, a barrel-like shape due to impurity diffusion occurring at a substantially center position in the depth direction Z due to the activation annealing. Therefore, in the FLRs 141 to 158, the impurity concentration is highest in portions where the width w40 is widest, and the impurity diffusion occurring due to the activation annealing is, for example, about 1×10¹⁸/cm³. In the FLRs 141 to 158, the impurity concentration of portions excluding the portions where the width w40 is widest is, for example, about 1×10¹⁷/cm³ at which impurity diffusion does not occur due to the activation annealing.

Conditions for the average impurity concentration of the FLRs 141 to 158 are the same as the conditions for the impurity concentration of the FLRs 101 to 118 in the first embodiment. Preferably, the portions of the FLRs 141 to 158 where the width w40 is widest (portions where the impurity concentration is highest) may be set so that the length w20 of the edge termination region 2 becomes as short as possible. Conditions for the first interval w41 between the portion where the width w40 is widest in the FLR 141 that is closest to the chip center and the outer peripheral pt-type region 62a are the same as the conditions for the first interval w1 between the innermost FLR 101 and the outer peripheral p⁺-type region 62a in the first embodiment.

Conditions for second to eighteenth 18 intervals w42, w43, w44, w45, w46, w47, w48, w49, w50, w51, w52, w53, w54, w55, w56, w7, w58 respectively between portions where the width w40 is widest in adjacent FLRs of the FLRs 141 to 158 are the same as the conditions for the second to the eighteenth intervals w2 to w18 respectively between adjacent FLRs of the FLRs 101 to 118 in the first embodiment. Depth positions of the ends (upper ends and lower ends) of the FLRs 141 to 158 in the depth direction Z are the same as those for the FLRs 101 to 118 in the first embodiment. Conditions for a thickness (length in the depth direction Z) t12 of the FLRs 141 to 158 are the same as those for the thickness t10 of each of the FLRs 101 to 118 in the first embodiment.

A method of manufacturing the semiconductor device 100b according to the third embodiment includes, in the method of manufacturing the semiconductor device 30 according to the first embodiment, forming the FLRs 141 to 158 by multistage ion implantation divided into multiple sessions (multiple stages) in which a predetermined dose amount is ion-implanted in the n⁻-type epitaxial layer 72 (72a, 72b) under different conditions using the same ion implantation mask. For example, in an instance in which the multistage ion implantation is divided into 9 stages, the multistage ion implantation is performed so that 2 stages are performed close to the upper ends and 2 stages are performed close to the lower ends of the FLRs 141 to 158, using a low dose amount by which impurity diffusion does not occur during activation annealing.

Five stages of the multistage ion implantation are performed close to substantially center positions of the FLRs 141 to 158 in the depth direction Z, using a high dose amount by which impurity diffusion occurs during the activation annealing. In an instance in which the impurity concentration close to the substantially center positions of the FLRs 141 to 158 in the depth direction Z is, for example, about 1×10¹⁸/cm³ due to the 5 stages of the multistage ion implantation, portions close to the substantially center positions of the FLRs 141 to 158 in the depth direction Z may be relatively widened by about 0.3 μm on each side (side facing chip center and side facing chip end, for a total of about 0.6 μm) in the direction of the normal as a result of impurity diffusion during the activation annealing.

The FLRs 141 to 158 may be formed concurrently with the first and the second pt-type regions 61, 62 (including the outer peripheral pt-type region 62a). In this instance, the first and the second pt-type regions 61, 62 (including the outer peripheral pt-type region 62a) have, in a cross-sectional view thereof, a shape in which the width at substantially a same depth as a center position of the FLRs 141 to 158 in the depth direction Z is relatively wide. The FLRs 141 to 158 may be formed by a process different from that for the first and the second pt-type regions 61, 62 (including the outer peripheral pt-type region 62a) and the impurity concentration distribution in the depth direction Z for the FLRs 141 to 158 may differ from that for the first and the second pt-type regions 61, 62.

As described above, according to the third embodiment, even in an instance in which a shape of the FLRs in a cross-sectional view thereof is variously changed, the impurity concentration and the depth of the FLRs assume the same predetermined conditions as those of the first embodiment, whereby effects similar to those of the first embodiment may be obtained.

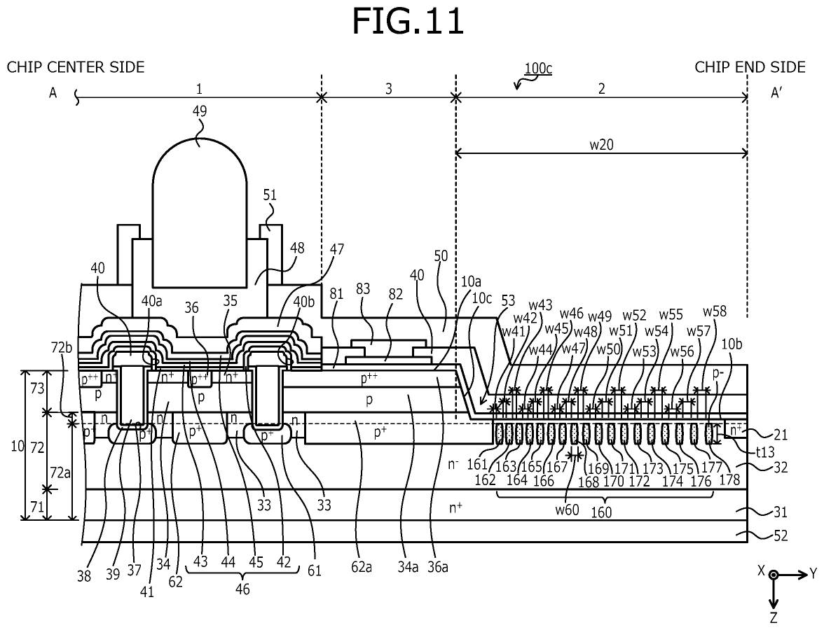

Next, a structure of a semiconductor device according to a fourth embodiment is described. FIG. 11 is a cross-sectional view depicting the structure of the semiconductor device according to the fourth embodiment. A layout when a semiconductor device 100c according to the fourth embodiment is viewed from the front side of the semiconductor substrate 10 is the same as that depicted in FIG. 1. The semiconductor device 100c according to the fourth embodiment depicted in FIG. 11 includes a FLR structure 160 in which the FLR structure 120 of the semiconductor device 100a according to the second embodiment (refer to FIG. 9) is applied to the FLR structure 140 of the semiconductor device 100b according to the third embodiment (refer to FIG. 10).

In other words, in the fourth embodiment, similarly to the third embodiment, FLR (p⁻-type regions) 161, 162, 163, 164, 165, 166, 167, 168, 169, 170, 171, 172, 173, 174, 175, 176, 177, 178 configuring the FLR structure 160, each has, in a cross-sectional view thereof, a barrel-like shape in which a width w60 is relatively wider at a substantially center position in the depth direction Z. Additionally, similarly to the second embodiment, the n⁻-type drift region 32 is provided between the second surface portion 10b of the front surface of the semiconductor substrate 10 and the FLRs 161 to 178. The FLRs 161 to 178 are not exposed at the second surface portion 10b of the front surface of the semiconductor substrate 10.

Conditions for the impurity concentration of the FLRs 161 to 178 are the same as the conditions for the impurity concentration of the FLRs 141 to 158 in the third embodiment. Preferably, in the FLRs 161 to 178, respective portions where the width w60 is widest (portions where the impurity concentration is highest) may be set so that the length w20 of the edge termination region 2 becomes as short as possible, similarly to the third embodiment. Conditions for the first interval w41 between the portion of the FLR 161 where the width w60 is widest (the FLR 161 being closest to the chip center of the FLRs) and the outer peripheral p⁺-type region 62a are the same as the conditions for the first interval w1 between the innermost FLR 101 and the outer peripheral pt-type region 62a in the first embodiment.

Conditions for second to eighteenth intervals w42, w43, w44, w45, w46, w47, w48, w49, w50, w51, w52, w53, w54, w55, w56, w67, w58 respectively between portions where the width w60 is widest in adjacent FLR of the FLRs 161 to 178 are the same as the conditions for the second to the eighteenth intervals w2 to w18 respectively between adjacent FLRs of the FLRs 101 to 118 in the first embodiment. Depth positions of the ends (upper ends and lower ends) of the FLRs 161 to 178 are the same as those for the FLRs 121 to 138 in the second embodiment. Conditions for a thickness (length in the depth direction Z) t13 of the FLRs 161 to 178 are the same as those for the thickness t10 of each of the FLRs 101 to 118 in the first embodiment.

A method of manufacturing the semiconductor device 100c according to the fourth embodiment includes in the method of manufacturing the semiconductor device 100b according to the third embodiment, forming the FLRs 161 to 178 only in the n⁻-type epitaxial layer 72a similarly to the first p⁺-type regions 61 (refer to FIG. 5) and not in the n⁻-type epitaxial layer 72b deposited on the n⁻-type epitaxial layer 72a. As a result, at a deep position not reaching the surface of the n⁻-type epitaxial layer 72 (72a, 72b) constituting the second surface portion 10b of the front surface of the semiconductor substrate 10, the FLRs 161 to 178 each having the barrel-like shape in a cross-sectional view thereof may be formed.

As described above, according to the fourth embodiment, effects similar to those of the first to third embodiments may be obtained.

The first interval w1 between the FLR 101 that is closest to the chip center (first FLR from the chip center) and the outer peripheral p⁺-type region 62a was verified. FIG. 12 is a characteristics diagram showing results of simulation of a relationship between breakdown voltage and the first interval between a main pn junction and the FLR closest to the chip center in the example. The main pn junction is a pn junction between the outer peripheral p⁺-type region 62a and the n⁻-type drift region 32. In FIG. 12, a horizontal axis represents the first interval w1 between the innermost FLR 101 and the outer peripheral p⁺-type region 62a while a vertical axis represents the breakdown voltage.

In FIG. 12, in an instance in which the first interval w1=0.0 μm, the innermost FLR 101 is disposed at a position to be right in contact with the outer peripheral p⁺-type region 62a. In an instance in which the first interval w1<0.0 μm, the innermost FLR 101 is disposed at a position to overlap and be in contact with the outer peripheral p⁺-type region 62a. In an instance in which the first interval w1>0.0 μm, the innermost FLR 101 is disposed to be apart from the outer peripheral p⁺-type region 62a.

For the semiconductor device 30 according to the first embodiment (hereinafter, “example”, refer to FIG. 2) described above, results of simulation of the breakdown voltage by variously changing the first interval w1 between the innermost FLR 101 and the outer peripheral p⁺-type region 62a are shown in FIG. 12. FIG. 12 shows results of simulating the breakdown voltage for the conventional semiconductor device 260 (hereinafter, “conventional example”, refer to FIG. 19) by variously changing an interval w211 between the outer peripheral p⁺-type region 262a and the FLR 291 that of the FLRs 291, is closest to the chip center.

In the example, the impurity concentration and the thickness t10 of the FLRs 101 to 118 of the FLR structure 20 were assumed to be 5×10¹⁷/cm³ and 1 μm, respectively. Under a condition that the breakdown voltage becomes 1200V, the width w21 of each of the FLRs 101 to 118 of the FLR structure 20, the second to the eighteenth intervals w2 to w18 respectively between adjacent FLRs of the FLRs 101 to 118, etc. were set. The length w20 of the edge termination region 2 in the example was 100 μm.

The first interval w1 between the innermost FLR 101 and the outer peripheral pt-type region 62a was assumed to be 1.0 μm and the increase amount of the second to the eighteenth intervals w2 to w18 respectively between adjacent FLRs of the FLRs 101 to 118 was assumed to be 0.1 μm. In other words, the second to the eighteenth intervals w2 to w18 respectively between adjacent FLRs of the FLRs 101 to 118 were assumed to be w2=1.1 μm, w3=1.2 μm, . . . , wi=1.0 μm+0.1 μm×(i−1) (where, i=4 to 18).

In the conventional example, the impurity concentration and the thickness t201 of the FLRs 291 of the FLR structure 290 were assumed to be 1×10¹⁸/cm³ and 0.5 μm, respectively. Under a condition that the breakdown voltage becomes 1200V, the width w210 of the FLRs 291 of the FLR structure 290, the interval w212 between adjacent FLRs of the FLRs 291, etc. were set. The FLRs 291 configuring the FLR structure 290 are disposed at equal intervals. The length w202 of the edge termination region 202 in the conventional example was 200 μm.

From the results shown in FIG. 12, it was found that in the example, the margin of the first interval w1 between the innermost FLR 101 and the outer peripheral pt-type region 62a realizing the predetermined breakdown voltage (1200V) was large and the breakdown voltage could be enhanced compared to the conventional example. Further, it was confirmed that in the example, the length w20 of the edge termination region 2 could be set to be ½ compared to the length w20 of the edge termination region 22 in the conventional example. A reason for this is as follows.

In the conventional example, the impurity concentration of the FLRs 291 is high and the margin of the interval w211 between the FLR 291 closest to the chip center of the FLRs 291 and the outer peripheral pt-type region 262a is small. Further, when the impurity concentration of the FLRs 291 is high and the depth (the thickness t201) of the FLRs 291 is shallow, electric field applied to the FLRs 291 increases and the interval w212 between adjacent FLRs of the FLRs 291 has to be secured to some extent, whereby the length w202 of the edge termination region 202 increases.

In contrast, in the example, the impurity concentration of the FLRs 101 to 118 is one order of magnitude smaller than the impurity concentration of the FLRs 291 in the conventional example, and the depth (the thickness t10) of the FLRs 101 to 118 is about two times deeper than the FLRs 291 in the conventional example. As a result, compared to the conventional example, the margin of the first interval w1 between the innermost FLR 101 and the outer peripheral pt-type region 62a may be sufficiently increased.

Further, in the example, the impurity concentration of the FLRs 101 to 118 is low and the depth of the FLRs 101 to 118 is deep, whereby electric field applied to the FLRs 101 to 118 decreases and compared to the conventional example, the second to the eighteenth intervals w2 to w18 respectively between adjacent FLRs of the FLRs 101 to 118 may be reduced. As a result, the length w20 of the edge termination region 2 may be reduced to a same extent as in an instance in which the spatially modulated FLR structure 220 (refer to FIG. 18) is disposed.

Further, from the results depicted in FIG. 12, it was confirmed that in the example, when the first interval w1 between the innermost FLR 101 and the outer peripheral pt-type region 62a exceeds 1.2 μm, while the predetermined breakdown voltage can be secured, the breakdown voltage decreases the wider is the first interval w1. On the other hand, it was confirmed that even when the innermost FLR 101 was in contact with the outer peripheral pt-type region 62a (w1—0.0 μm), the breakdown voltage could be sufficiently secured without the breakdown voltage decreasing.

Four other conditions of the FLR structure 20 were verified. First, as a first verification, the impurity concentration of the FLRs 101 to 118 was verified. FIG. 13 is a characteristics diagram showing results of simulation of a relationship between the impurity concentration of FLRs in an experimental example and breakdown voltage. In FIG. 13, a vertical axis and a horizontal axis are the same as those as in FIG. 12. In the semiconductor device 30 according to the first embodiment described above (refer to FIG. 2), the impurity concentration of the FLRs 101 to 118 was changed (hereinafter, first, second, and third experimental examples) and the breakdown voltage was simulated.

For the first to the third experimental examples, results of simulating the breakdown voltage by variously changing the first interval w1 between the innermost FLR 101 and the outer peripheral pt-type region 62a are shown in FIG. 13. In the first to the third experimental examples, the impurity concentration of the FLRs 101 to 118 was assumed to be 3×10¹⁷/cm³, 5×10¹⁷/cm³, and 9×10¹⁷/cm³, respectively. Configuration of the first to the third experimental examples excluding the impurity concentration of the FLRs 101 to 118 was similar to that of the example in FIG. 12. The second experimental example corresponds to the example in FIG. 12.

From the results shown in FIG. 13, it was confirmed that in the first to the third experimental examples as well, when the first interval w1 between the innermost FLR 101 and the outer peripheral pt-type region 62a is at most 1.2 μm, the predetermined breakdown voltage (1200V) could be sufficiently obtained. Therefore, the impurity concentration of the FLRs 101 to 118 is assumed to be in a range of 3×10¹⁷/cm³ to 9×10¹⁷/cm³ and the first interval w1 between the innermost FLR 101 and the outer peripheral pt-type region 62a is assumed to be at most 1.2 μm, whereby the predetermined breakdown voltage may be sufficiently obtained.

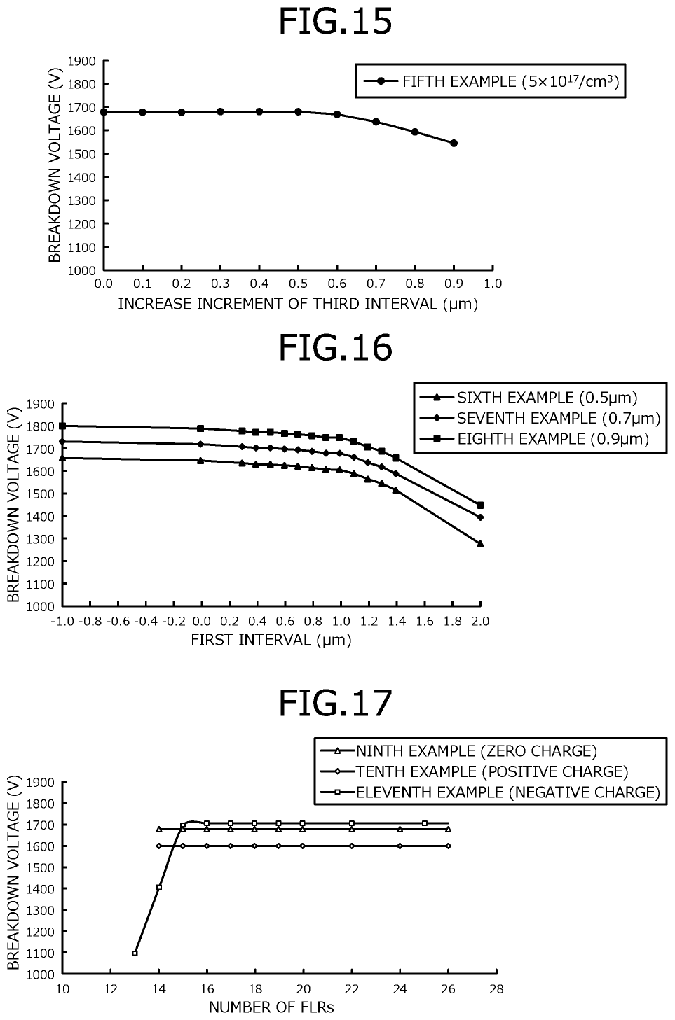

As a second verification, the increase amount of the second interval w2 between the FLRs 101, 102 adjacent to each other and the increase amount of the third interval w3 between the FLRs 102, 103 adjacent to each other was verified. FIG. 14 is a characteristics diagram showing results of simulation of a relationship between the breakdown voltage and the increase amount of the second interval between the first and the second FLRs from the chip center in the experimental example. FIG. 15 is a characteristics diagram showing results of simulation of a relationship between the breakdown voltage and the increase amount of the third interval between the second and the third FLRs from the chip center in the experimental example.

In FIG. 14, a horizontal axis represents the increase amount of the second interval w2 between the FLRs 101, 102 (between the innermost FLR 101 and the FLR 102 that is second from the chip center) adjacent to each other while a vertical axis represents the breakdown voltage. In FIG. 15, a horizontal axis represents the increase amount of the third interval w3 between the FLRs 102, 103 (between the FLR 102 that is second from the chip center and the FLR 103 that is third from the chip center) adjacent to each other while a vertical axis represents the breakdown voltage.

For the semiconductor device 30 according to the first embodiment described above (hereinafter, fourth experimental example, refer to FIG. 2), results of simulating the breakdown voltage by increasing the increase amount of the second interval w2 between the FLRs 101, 102 that are adjacent to each other are shown in FIG. 14. For the semiconductor device 30 according to the first embodiment described above (hereinafter, fifth experimental example, refer to FIG. 2), results of simulating the breakdown voltage by variously changing the increase amount of the third interval w3 between the FLRs 102, 103 that are adjacent to each other are shown in FIG. 15.

The increase amount of the second interval w2 between the FLRs 101, 102 that are adjacent to each other is an increase amount (=w2−w1) from the first interval w1 between the innermost FLR 101 and the outer peripheral p⁺-type region 62a. The increase amount of the third interval w3 between the FLRs 102, 103 that are adjacent to each other is an increase amount (=w3−w2) from the second interval w2. In the fourth experimental example, configuration other than the second interval w2 is the same as that in the example in FIG. 12. In the fifth experimental example, configuration other than the third interval w3 is the same as that in the example in FIG. 12.

From the results shown in FIGS. 14 and 15, it was confirmed that when the increase amount of the second to the eighteenth intervals w2 to w18 respectively between adjacent FLRs of the FLRs 101 to 118 is at most 0.7 μm, even when the interval between an adjacent two of the FLRs increases by the predetermined increase amount the closer the adjacent two of the FLRs are disposed to the chip end, according to an increase in the number of FLRs, the breakdown voltage is not adversely affected. Relationships between the breakdown voltage and the increase amounts of the fourth to the eighteenth intervals w4 to w18 between adjacent FLRs of the FLRs 103 to 118 (not depicted) exhibited similar trends as those in FIGS. 14 and 15.

As a third verification, the thickness (depth) t10 of the FLRs 101 to 118 was verified. FIG. 16 is a characteristics diagram showing results of simulation of a relationship between FLR thickness and the breakdown voltage in the experimental example. In FIG. 16, a vertical axis and a horizontal axis are similar to those in FIG. 12. In the semiconductor device 30 according to the first embodiment described above (refer to FIG. 2), the breakdown voltage was simulated by changing the thickness t10 of each of the FLRs 101 to 118 (hereinafter, sixth, seventh, and eighth experimental examples).

For the sixth to the eighth experimental examples, results of simulating the breakdown voltage by variously changing the first interval w1 between the innermost FLR 101 and the outer peripheral pt-type region 62a are shown in FIG. 16. In the sixth to the eighth experimental examples, the thickness t10 of each of the FLRs 101 to 118 was assumed to be 0.5 μm, 0.7 μm, and 0.9 μm, respectively. Configuration of the sixth to the eighth experimental examples other than the thickness t10 of each of the FLRs 101 to 118 is the same as that in the example in FIG. 12.

From the results shown in FIG. 16, it was confirmed that by setting the impurity concentration of the FLRs 101 to 118 to 5×10¹⁷/cm³ and the thickness t10 of each of the FLRs 101 to 118 to be in a range of about 0.5 μm to 0.9 μm, the predetermined breakdown voltage (1200V) may be sufficiently obtained. While not depicted, even in an instance in which the impurity concentration of the FLRs 101 to 118 was set to be in a range of 3×10¹⁷/cm³ to 9×10¹⁷/cm³, the relationship between the thickness t10 of each of the FLRs 101 to 118 and the breakdown voltage exhibited similar trends as those in FIG. 16.

As a fourth verification, the number of the FLRs of the FLR structure 20 was verified. FIG. 17 is a characteristics diagram showing results of simulation of a relationship between the number of FLRs of the FLR structure in the experimental example and the breakdown voltage. In FIG. 17, a horizontal axis represents the number of the FLRs of the FLR structure 20 while a vertical axis represents the breakdown voltage. FIG. 17 includes results of simulating external charge dependence of the FLRs of the FLR structure 20. External charge is positive charge when the insulating layer on the FLRs is positively charge or is negative charge when the insulating layer is negatively charged.

With respect to the semiconductor device 30 according to the first embodiment described above (refer to FIG. 2), the breakdown voltage was simulated for an instance in which the insulating layer (insulating layer in which the field oxide film 81, the interlayer insulating film 40, and the first protective film 50 are sequentially stacked on the FLRs) on the second surface portion 10b of the front surface of the semiconductor substrate 10 in the edge termination region 2 is not charged (zero charge), an instance in which the insulating layer is positively charged (positive charge), and an instance in which the insulating layer is negatively charged (negative charge) (hereinafter, ninth, tenth, and eleventh experimental examples).

For the ninth to eleventh experimental examples, results of simulating the breakdown voltage by variously changing the number of the FLRs of the FLR structure 20 are shown in FIG. 17. Configuration of the ninth to eleventh experimental examples other than the number of the FLRs of the FLR structure 20 is the same as that in the example in FIG. 12. The ninth experimental example corresponds to the example in FIG. 12. The ninth experimental example is simulation results for an instance of use under a low-humidity environment (room ventilated by general air conditioning control, etc.) and corresponds to results obtained by a general voltage application test according to actual use.

The tenth experimental example (insulating layer is positively charged) is simulation results in an instance of use under a high-humidity environment (for example, under a special environment such as a factory) and correspond to results obtained by a temperature humidity bias (THB) test. Under a high-humidity environment, the insulating layer on the second surface portion 10b of the front surface of the semiconductor substrate 10 in the edge termination region 2 was positively charged, spreading of the depletion layer from the active region 1 to the chip end became difficult, and the breakdown voltage and leak current varied. Therefore, the tenth experimental example verified variation of the breakdown voltage and leak current under a high-humidity environment.

The eleventh experimental example (insulating layer is negatively charged) is simulation results when high voltage is applied between the drain and source and corresponds to results obtained by a high-voltage application test. Due to the depletion layer that spreads toward the chip end, from the active region 1 when the MOSFET is OFF, when a surface region at the front surface of the semiconductor substrate 10 in the edge termination region 2 is depleted, the state becomes the same as that when this depleted portion is positively charged. As a result, negative charge accumulates in the insulating layer on the second surface portion 10b of the front surface of the semiconductor substrate 10 in the edge termination region 2.

While negative charge accumulated in the insulating layer is discharged and does not have any adverse effects when voltage application between the drain and source is for a short period, when a high voltage at least equal to the breakdown voltage (for example, high voltage of about 1400V or 1500V in an instance of a breakdown voltage of 1200V) is continuously applied between the drain and source for a long period (for example, about 3000 hours), the accumulated charge is not discharged and the depletion layer spreads closer to the chip end, causing the breakdown voltage and leak current to vary. Therefore, the eleventh experimental example verifies variation of the breakdown voltage and leak current during high-voltage application between the drain and source for long periods.

From the results depicted in FIG. 17, it was confirmed that regardless of the presence or absence of external charge, when the number of the FLRs of the FLR structure 20 is at least 16, the predetermined breakdown voltage (1200V) may be sufficiently obtained. A reason for this is that, compared to the conventional example (refer to FIG. 19), the thickness t10 of the FLRs is thick and the FLRs reach deeper positions from the second surface portion 10b of the front surface of the semiconductor substrate 10 in the edge termination region 2, whereby adverse effects of external charge accumulated in the insulating layer on the second surface portion 10b of the front surface of the semiconductor substrate 10 in the edge termination region 2 may be suppressed.

While not depicted, in the conventional example as well, adverse effects due to external charge accumulated in the insulating layer on the second surface portion 210b of the front surface of the semiconductor substrate 210 in the edge termination region 202 exhibited similar trends as those in FIG. 17. Nonetheless, it was confirmed by the inventor that in conventional example, similarly to the margin of the interval w211 between the FLR 291 closest to the chip center of the FLRs 291 and the outer peripheral pt-type region 262a (refer to FIG. 12), the margin of the FLRs 291 of the FLR structure 290 satisfying the predetermined breakdown voltage is small compared to the ninth to the eleventh experimental examples.

In the foregoing, the present invention is not limited to the embodiments described above and various modifications within a range not departing from the spirit of the invention are possible. For example, in the first and the second embodiments, to mitigate electric field applied to the gate insulating film at the bottoms of the gate trenches, pt-type regions provided close to the bottoms of the gate trenches may each have, in a cross-sectional view thereof, a barrel-like shape with a relatively wide width at a substantially center position in the depth direction. The present invention is applicable in instances in which, instead of silicon carbide, a wide band gap semiconductor other than silicon carbide is used as a semiconductor material. Further, the present invention is similarly implemented when the conductivity types (n-type, p-type) are reversed.

As described above, the margin of the intervals between adjacent second-conductivity-type voltage withstanding regions (FLRs) may be increased, whereby the precision of the voltage withstanding structure may be increased. Further, by increasing the margin of the intervals between adjacent second-conductivity-type voltage withstanding regions (FLRs), adverse effects of the accuracy of ion implantation for forming the second-conductivity-type voltage withstanding regions are suppressed and design of the voltage withstanding structure is facilitated.

The semiconductor device according to the present invention achieves effects in that a semiconductor device having high reliability and for which fabrication is facilitated may be provided.

As described above, the semiconductor device according to the present invention is useful for power semiconductor devices that control high voltage and/or large currents.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device having an active region through which a main current flows and a termination region surrounding a periphery of the active region, the semiconductor device comprising:
a semiconductor substrate containing a semiconductor having a band gap wider than a band gap of silicon, the semiconductor substrate having a first main surface and a second main surface opposite to each other;
a first semiconductor region of a first conductivity type, provided in the semiconductor substrate;
a second semiconductor region of a second conductivity type, provided in the active region, between the first main surface of the semiconductor substrate and the first semiconductor region;
a device element structure formed in the active region, and including a pn junction between the second semiconductor region and the first semiconductor region;
a first electrode electrically connected to the second semiconductor region;
a second electrode provided on the second main surface of the semiconductor substrate; and
a plurality of second-conductivity-type voltage withstanding regions selectively provided apart from one another in the first semiconductor region, in surface regions of the semiconductor substrate at the first main surface thereof in the termination region, the second-conductivity-type voltage withstanding regions each concentrically surrounding the periphery of the active region, wherein
the second-conductivity-type voltage withstanding regions have an impurity concentration that is less than 1×10¹⁸/cm³, and
the second-conductivity-type voltage withstanding regions have a thickness in a range of 0.7 μm to 1.1 μm.

2. The semiconductor device according to claim 1, wherein the impurity concentration of the second-conductivity-type voltage withstanding regions is in a range of 3×10¹⁷/cm³ to 9×10¹⁷/cm³.

3. The semiconductor device according to claim 1, the comprising a second-conductivity-type high-concentration region selectively provided between the second semiconductor region and the first semiconductor region, and in contact with the second semiconductor region, the second-conductivity-type high-concentration region surrounding the periphery of the active region and having an impurity concentration higher than an impurity concentration of the second semiconductor region, wherein
the second-conductivity-type high-concentration region is provided between the active region and the second-conductivity-type voltage withstanding regions and faces the second-conductivity-type voltage withstanding regions in a direction parallel to the first main surface of the semiconductor substrate.

4. The semiconductor device according to claim 3, wherein a first interval between the second-conductivity-type high-concentration region and an innermost one of the second-conductivity-type voltage withstanding regions is at most 1.2 μm, the innermost one being closest among the second-conductivity-type voltage withstanding regions to the active region.

5. The semiconductor device according to claim 3, wherein an innermost one of the second-conductivity-type voltage withstanding regions is in contact with the second-conductivity-type high-concentration region, the innermost one being closest among the second-conductivity-type voltage withstanding regions to the active region.

6. The semiconductor device according to claim 5, wherein a second interval between the innermost one of the second-conductivity-type voltage withstanding regions and a second one of the second-conductivity-type voltage withstanding regions is at most 2.1 μm, the second one being second among the second-conductivity-type voltage withstanding regions from the active region.

7. The semiconductor device according to claim 5, wherein among the second-conductivity-type voltage withstanding regions, a third interval between a second one of the second-conductivity-type voltage withstanding regions and a third one of the second-conductivity-type voltage withstanding regions is at most 3.1 μm, the second one being second from the active region and the third one being third from the active region.

8. The semiconductor device according to claim 7, wherein the third interval is at most 1.0 μm.

9. The semiconductor device according to claim 8, wherein among the second-conductivity-type voltage withstanding regions, a fourth interval between the third one of the second-conductivity-type voltage withstanding regions and a fourth one of the second-conductivity-type voltage withstanding regions is at most 2.0 μm, the fourth one being fourth from the active region.

10. The semiconductor device according to claim 4, wherein an interval between an adjacent two of the second-conductivity-type voltage withstanding regions at least fourth from the active region and adjacent to each other is wider than the first interval.

11. The semiconductor device according to claim 1, wherein the second-conductivity-type voltage withstanding regions all have a same width that is a shortest length of the second-conductivity-type voltage withstanding regions in a direction parallel to the first main surface of the semiconductor substrate.

12. The semiconductor device according to claim 1, wherein each second-conductivity-type voltage withstanding region has a width that is a shortest length of said each second-conductivity-type voltage withstanding region in a direction parallel to the first main surface of the semiconductor substrate, and
the width of a second and subsequent ones of the second-conductivity-type voltage withstanding regions at least second from the active region is wider than the width of an innermost one of the second-conductivity-type voltage withstanding regions closest to the active region.

13. The semiconductor device according to claim 1, wherein the second-conductivity-type voltage withstanding regions reach the first main surface of the semiconductor substrate.

14. The semiconductor device according to claim 1, wherein
the second-conductivity-type voltage withstanding regions are provided at a depth position apart from the first main surface of the semiconductor substrate, and
the first semiconductor region intervenes between the first main surface of the semiconductor substrate and the second-conductivity-type voltage withstanding regions.

15. The semiconductor device according to claim 1, wherein the second-conductivity-type voltage withstanding regions each have, in a cross-sectional view thereof, a rectangular shape or a barrel-like shape having a width that is relatively wider at a center position in a depth direction.

16. The semiconductor device according to claim 1, wherein a portion of the first main surface of the semiconductor substrate in the termination region is free of a conductive film.

17. The semiconductor device according to claim 1, wherein a portion of the first main surface of the semiconductor substrate in the termination region is covered by an insulating layer.
